(19) United States
(12) Patent Application Publication
(10) Pub. No.: US 2026/0279409 A1
(43) Pub. Date: Sep. 17, 2026

(54) SEMICONDUCTOR STORAGE DEVICE AND MANUFACTURING METHOD OF SEMICONDUCTOR STORAGE DEVICE

(71) Applicant: Kioxia Corporation, Tokyo (JP)

(72) Inventors: Takuya SUZUKI, Yokkaichi Mie (JP); Keisuke SUDA, Yokkaichi Mie (JP)

(73) Assignee: Kioxia Corporation, Tokyo (JP)

(21) Appl. No.: 19/238,652

(22) Filed: Jun. 16, 2025

(30) Foreign Application Priority Data
Mar. 14, 2025 (JP) 2025-041100

(51) Int. Cl. G11C 5/06; H10B 43/10; H10B 43/27; H10B 43/35; H10D 30/01; H10D 30/69

(52) U.S. Cl. CPC G11C 5/063; H10B 43/10; H10B 43/27; H10B 43/35; H10D 30/0413; H10D 30/693

(57) ABSTRACT

A semiconductor storage device according to an embodiment includes a multi-layered body, an interlayer-insulating film, a plate-shaped part, and a support column part. The multi-layered body includes a plurality of conductive layers and a plurality of insulating layers. The multi-layered body has an upper part and a lower part. The plurality of conductive layers include a staircase portion. The staircase portion has a staircase shape. The interlayer-insulating film covers the staircase portion. The plate-shaped part extends in a first direction and penetrates the multi-layered body in a stacking direction. The plate-shaped part is intermittent in the first direction via intermittent portions. The support column part is in the intermittent portion. The support column part penetrates the multi-layered body in the stacking direction and reaches the upper part from the lower part.

### CROSS-REFERENCE TO RELATED APPLICATION

Priority is claimed on Japanese Patent Application No. 2025-041100 filed on Mar. 14, 2025, the content of which is incorporated herein by reference.

### FIELD

Embodiments of the present invention relate to a semiconductor storage device and a manufacturing method of a semiconductor storage device.

### BACKGROUND ART

In recent years, semiconductor devices including three-dimensionally integrated memory cells have been proposed. In such a semiconductor device, a through hole is formed in a multi-layered body including insulating layers and conductive layers which are alternately stacked. A memory layer and a semiconductor layer capable of storing charges are formed on an inner surface of the through hole. Therefore, a memory cell is formed between the memory layer and the conductive layer.

Also, in a semiconductor storage device including memory cells, a structure is known in which a staircase portion is formed in a part of conductive layers of a multi-layered body and thereby contacts are connected to the conductive layers of the staircase portion.

### BRIEF DESCRIPTION OF THE DRAWINGS

FIG. 1 is a partial top view showing a schematic configuration of a semiconductor storage device according to a first embodiment.

FIG. 2 is a cross-sectional view showing a detailed configuration of a cell array region in the semiconductor storage device according to the first embodiment.

FIG. 3 is a cross-sectional view showing a detailed configuration of a staircase region in the semiconductor storage device according to the first embodiment.

FIG. 4 is a cross-sectional view showing a detailed configuration of the staircase region in the semiconductor storage device according to the first embodiment.

FIG. 5 is a partial top view showing a schematic configuration of the staircase region in the semiconductor storage device according to the first embodiment.

FIG. 6 is a cross-sectional view showing a schematic configuration of the staircase region in the semiconductor storage device according to the first embodiment.

FIG. 7 is a partial top view showing a schematic configuration of a staircase region in a semiconductor storage device of comparative example 1.

FIG. 8 is a cross-sectional view showing a schematic configuration of the staircase region in the semiconductor storage device of comparative example 1.

FIG. 9 is a cross-sectional view showing a state during manufacturing of the staircase region in the semiconductor storage device of comparative example 1.

FIG. 10 is a cross-sectional view showing a state during manufacturing of the staircase region in the semiconductor storage device of comparative example 1.

FIG. 11 is a cross-sectional view showing a state during manufacturing of the staircase region in the semiconductor storage device of comparative example 1.

FIG. 12 is a partial top view showing a schematic configuration of a staircase region in a semiconductor storage device according to a second embodiment.

FIG. 13 is a partial cross-sectional view showing a schematic configuration of the staircase region in the semiconductor storage device according to the second embodiment.

FIG. 14 is a partial cross-sectional view showing a schematic configuration of the staircase region in the semiconductor storage device according to the second embodiment.

FIG. 15 is a partial cross-sectional view showing a schematic configuration of a staircase region in a semiconductor storage device of comparative example 2.

FIG. 16 is a partial top view for explaining an example of a manufacturing method of the semiconductor storage device according to the first embodiment.

FIG. 17 is a partial top view for explaining an example of the manufacturing method of the semiconductor storage device according to the first embodiment.

FIG. 18 is a partial cross-sectional view for explaining an example of the manufacturing method of the semiconductor storage device according to the first embodiment.

FIG. 19 is a partial cross-sectional view for explaining an example of the manufacturing method of the semiconductor storage device according to the first embodiment.

FIG. 20 is a partial cross-sectional view for explaining an example of the manufacturing method of the semiconductor storage device according to the first embodiment.

FIG. 21 is a partial top view for explaining an example of the manufacturing method of the semiconductor storage device according to the first embodiment.

FIG. 22 is a partial cross-sectional view for explaining an example of the manufacturing method of the semiconductor storage device according to the first embodiment.

FIG. 23 is a partial top view showing a schematic configuration of a staircase region in a semiconductor storage device according to a third embodiment.

FIG. 24 is a partial top view showing a schematic configuration of the staircase region in the semiconductor storage device according to the third embodiment.

FIG. 25 is a partial top view showing a schematic configuration of a staircase region in a semiconductor storage device according to a fourth embodiment.

FIG. 26 is a partial top view showing a schematic configuration of a staircase region in a semiconductor storage device according to a fifth embodiment.

FIG. 27 is a partial top view showing a schematic configuration of a staircase region in a semiconductor storage device according to a sixth embodiment.

FIG. 28 is a partial top view showing a schematic configuration of a staircase region in a semiconductor storage device according to a seventh embodiment.

### DETAILED DESCRIPTION

A semiconductor storage device according to an embodiment includes a staircase region-side multi-layered body, an interlayer-insulating film, a plate-shaped part, and a support column part. In the staircase region-side multi-layered body, a plurality of conductive layers and a plurality of insulating layers are alternately stacked one by one. The staircase region-side multi-layered body has an upper part and a lower part. The plurality of conductive layers include a staircase portion. The staircase portion has a staircase shape extending in a first direction intersecting a stacking direction of the plurality of conductive layers. The interlayer-insulating film covers the staircase portion. The plate-shaped part extends in the first direction and penetrates the staircase region-side multi-layered body in the stacking direction. The plate-shaped part is intermittent in the first direction via intermittent portions. The support column part is in the intermittent portion. The support column part penetrates the staircase region-side multi-layered body in the stacking direction and reaches the upper part from the lower part.

### First Embodiment

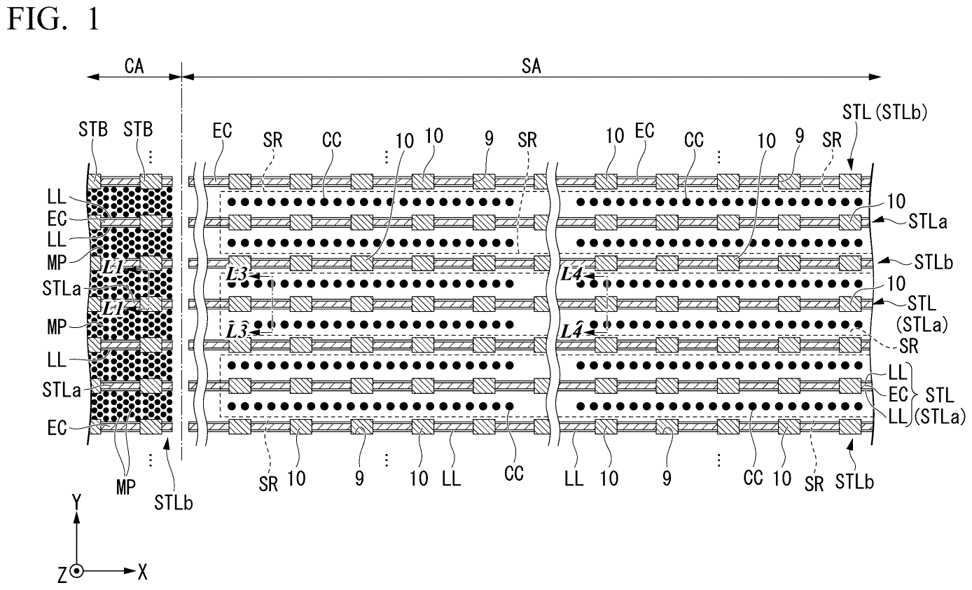

A configuration example of a semiconductor storage device 1 according to a first embodiment will be described below with reference to FIGS. 1 to 6. The semiconductor storage device 1 according to the embodiment has a cell array region CA and a staircase region SA.

FIG. 1 is a partial top view showing a schematic configuration of the semiconductor storage device 1 according to the first embodiment. FIG. 1 shows a part of each of the cell array region CA and the staircase region SA of the semiconductor storage device 1. An upper wiring, a plug, and the like are provided above the cell array region CA and the staircase region SA. In FIG. 1, illustration of the upper wiring, the plug, and the like is omitted.

In the present specification, an X direction and a Y direction indicate directions along orientations of surfaces of a plurality of conductive layers to be described later. The X direction and the Y direction are orthogonal to each other. Also, a direction intersecting the X direction and the Y direction, that is, a stacking direction of the plurality of conductive layers, is defined as a Z direction. The X direction is an example of a first direction. The Y direction is an example of a second direction. Furthermore, when it is desired to particularly distinguish directions opposite to the X, Y, and Z directions indicated by the arrows in each drawing, the opposite directions are denoted by adding “−” such as −X direction, −Y direction, −Z direction, or the like.

The cell array region CA has a multi-layered body (to be described later) on the side of the cell array region CA and a plurality of memory pillars MP (semiconductor pillars). The multi-layered body on the side of the cell array region CA is an example of a cell array region-side multi-layered body. In the multi-layered body on the side of the cell array region CA, a plurality of conductive layers and a plurality of insulating layers are alternately stacked one by one. The plurality of memory pillars MP penetrate the multi-layered body on the side of the cell array region CA in the Z direction.

The memory pillars MP are disposed in a grid pattern in an XY plane in FIG. 1. The memory pillars MP extend in the Z direction in FIG. 1.

The staircase region SA has a staircase portion SR. In the embodiment, the staircase portion SR has a predetermined length in the X direction. Also, a plurality of staircase portions SR extending in the X direction are apart from each other by a predetermined distance. The plurality of staircase portions SR extending in the X direction are disposed at predetermined intervals in the Y direction.

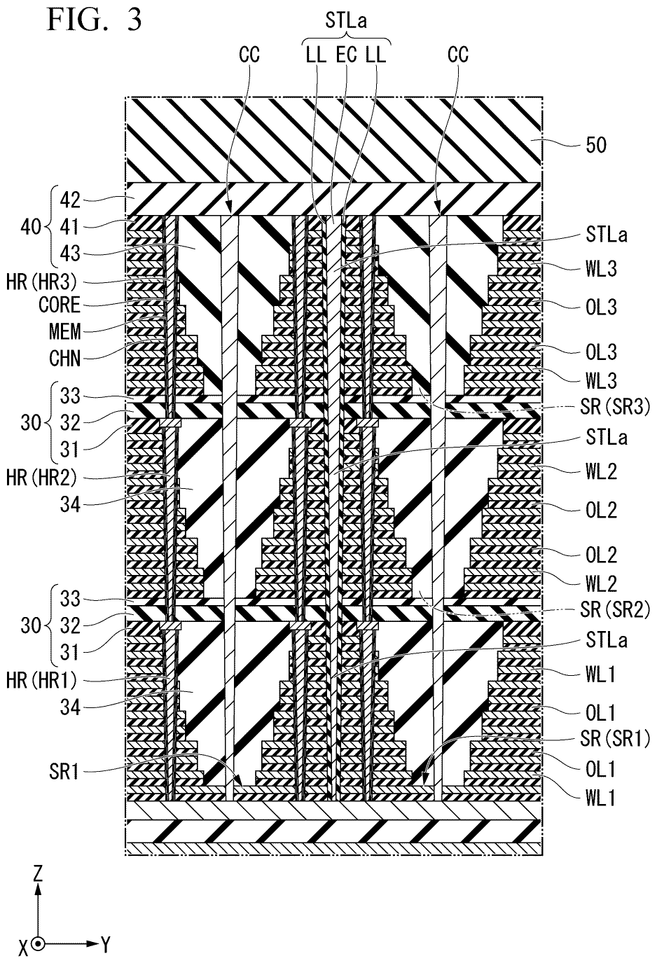

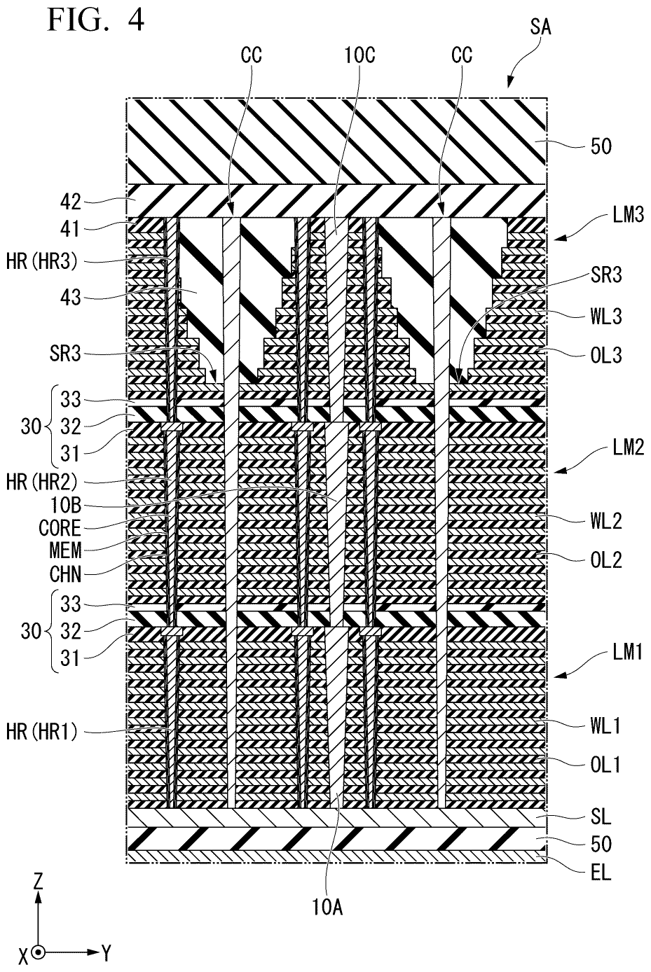

In the staircase portion SR, the multi-layered body is processed into a staircase shape so that each of the plurality of conductive layers forms a terrace surface (tread surface). The multi-layered body on the side of the staircase portion SR is an example of a staircase region-side multi-layered body. A third interlayer-insulating film 40 (see FIGS. 3 and 4) is formed at least above the multi-layered body. The third interlayer-insulating film 40 is, for example, a silicon oxide layer. Also, a plurality of contacts CC penetrating the third interlayer-insulating film 40 and connected to the terrace surface are provided in the staircase portion SR. Furthermore, in the present specification, a direction in which the terrace surfaces of a plurality of step portions constituting the staircase portion SR face is defined as an upward direction.

In the cell array region CA and the staircase region SA, a plurality of plate-shaped parts STL that divide the cell array region CA and the staircase region SA are formed. Each of the plurality of plate-shaped parts STL traverses the cell array region CA and the staircase region SA in the X direction. Each of the plurality of plate-shaped parts STL extends in the Z direction in FIG. 1 and terminates within a source line (to be described later). Also, each of the plate-shaped parts STL has a liner layer LL and a conductive portion EC positioned on an inner side of the liner layer LL. The liner layer LL is, for example, a silicon oxide layer. The conductive portion EC is made of a conductive material, such as a tungsten layer, a tungsten nitride layer, a titanium layer, a titanium nitride layer, a molybdenum layer, or a molybdenum nitride layer. The plate-shaped part STL connected to the source line (to be described later) at the conductive portion EC functions as a source line contact.

Furthermore, FIG. 1 shows a planar layout in which the plate-shaped parts STL extending in the X direction from the cell array region to the staircase region SA are aligned in the Y direction at predetermined intervals. Hereinafter, in the description of the present specification, among the plate-shaped part STL of the staircase region SA, the plate-shaped part STL extending to divide the staircase portions SR will be denoted as a staircase-side plate-shaped part STLa. The plate-shaped part STL extending along a space between the staircase portions SR spaced apart in the Y direction is denoted as a bridge-side plate-shaped part STLb.

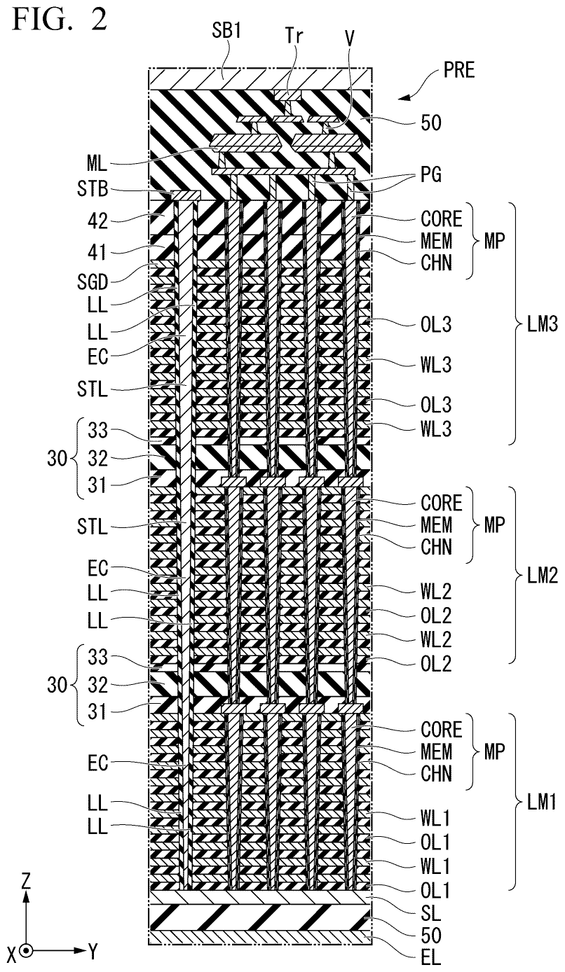

Next, detailed configurations of the cell array region CA and the staircase region SA will be described with reference to FIGS. 2 to 4. FIG. 2 is a cross-sectional view showing a detailed configuration of the cell array region CA according to the first embodiment. More specifically, FIG. 2 is a YZ cross-sectional view along line L1-L1 in FIG. 1. FIGS. 3 and 4 are cross-sectional views showing a detailed configuration of the staircase region SA according to the first embodiment. More specifically, FIG. 3 is a YZ cross-sectional view along line L3-L3 in FIG. 1. FIG. 4 is a YZ cross-sectional view along line L4-L4 in FIG. 1. In FIG. 2, illustration of a columnar portion HR to be described later is omitted.

As shown in FIGS. 2 to 4, the semiconductor storage device 1 includes a first multi-layered body LM1, a second multi-layered body LM2, and a third multi-layered body LM3. The first multi-layered body LM1 is positioned on a source line SL. The second multi-layered body LM2 is positioned above the first multi-layered body LM1. The third multi-layered body LM3 is positioned above the second multi-layered body LM2.

Furthermore, in the semiconductor storage device 1, the number of the stacked layers in the multi-layered body LM is optionally set. As the number of the stacked layers in the multi-layered body LM, an optionally-set number of the stacked layers, such as one layer or a plurality of layers, can be employed. In the embodiment, a three-layered structure having the first multi-layered body LM1, the second multi-layered body LM2, and the third multi-layered body LM3 which are stacked therein will be described below as an example.

The source line SL is, for example, a conductive polycrystalline silicon layer. The source line SL is disposed on an electrode film EL via an insulating layer 50. A plurality of plugs (not shown in the drawings) are disposed in the insulating layer 50. The source line SL and the electrode film EL maintain electrical continuity via the plug. Therefore, a source potential can be applied to the source line SL from outside the semiconductor storage device 1 via the electrode film EL and the plug.

The first multi-layered body LM1 has a configuration in which a plurality of conductive layers WL1 and a plurality of insulating layers OL1 are alternately stacked one by one. The second multi-layered body LM2 has a configuration in which a plurality of conductive layers WL2 and a plurality of insulating layers OL2 are alternately stacked one by one. Furthermore, the third multi-layered body LM3 has a configuration in which a plurality of conductive layers WL3 and a plurality of insulating layers OL3 are alternately stacked one by one.

The conductive layers WL1, WL2, and WL3 are, for example, a tungsten layer, a tungsten nitride layer, a titanium layer, a titanium nitride layer, a molybdenum layer, a molybdenum nitride layer, or the like. The insulating layers OL1, OL2, and OL3 are, for example, a silicon oxide layer, an aluminum oxide layer, or the like. Furthermore, the conductive layer WL1 is an example of a first conductive layer. The insulating layer OL1 is an example of a first insulating layer. Also, the conductive layer WL2 is an example of a second conductive layer. The insulating layer OL2 is an example of a second insulating layer. The conductive layer WL3 is an example of a third conductive layer. The insulating layer OL3 is an example of a third insulating layer.

Furthermore, in FIGS. 3 and 4, a suitable number of layers for explanation such as the conductive layers WL1, WL2, and WL3 and the insulating layers OL1, OL2, and OL3 are shown. The number of conductive layers WL1, WL2, and WL3 is not limited to the shown example, and may be determined as appropriate. For example, 48 conductive layers, 64 conductive layers, or 96 conductive layers may be formed.

Between the first multi-layered body LM1 and the second multi-layered body LM2, an insulating layer 31, an insulating layer 32, and an insulating layer 33 are stacked in that order to cover the first multi-layered body LM1. The insulating layers 31 to 33 are each formed to contain an insulating material such as, for example, a silicon oxide layer.

Between the second multi-layered body LM2 and the third multi-layered body LM3, the insulating layer 31, the insulating layer 32, and the insulating layer 33 are formed in that order to cover the second multi-layered body LM2. The insulating layers 31 to 33 are each formed to contain an insulating material such as, for example, a silicon oxide layer.

Above the third multi-layered body LM3, an insulating layer 41, an insulating layer 42, and an insulating layer 43 are formed in that order to cover the third multi-layered body LM3. The insulating layers 41 to 43 are each formed to contain an insulating material such as, for example, a silicon oxide layer.

As shown in FIGS. 1 and 2, the memory pillars MP (semiconductor pillars) and the plate-shaped parts STL are formed in the cell array region CA.

The memory pillar MP penetrates the first multi-layered body LM1, the insulating layers 31 to 33, the second multi-layered body LM2, the insulating layers 31 to 33, the third multi-layered body LM3, and the insulating layers 41 and 43 in the Z direction, and terminates within the source line SL. The memory pillar MP has a substantially columnar shape. The memory pillar MP has a core layer CORE, a channel layer CHN, and a memory film MEM that are concentrically formed from a center toward the outside. The memory pillar MP has a cap layer CAP on an upper part thereof. Here, the core layer CORE contains, for example, silicon oxide. The channel layer CHN and the cap layer CAP contain, for example, conductive polycrystalline silicon, amorphous silicon, or the like. Also, the memory film MEM also has a tunnel insulating layer, a charge storage layer, and a block insulating layer (which are not shown in the drawings) formed in that order in a direction from the center of the memory pillar MP toward the outside. The tunnel insulating layer and the block insulating layer include, for example, a silicon oxide layer or the like, and the charge storage layer includes, for example, a silicon nitride layer or the like.

The memory pillar MP formed in the first multi-layered body LM1 can be referred to as a first columnar body. The memory pillar MP formed in the second multi-layered body LM2 can be referred to as a second columnar body. The memory pillar MP formed in the third multi-layered body LM3 can be referred to as a third columnar body.

In each of the conductive layers WL1, WL2, and WL3, a memory cell (not shown in the drawings) is formed in a portion of the memory pillar MP facing the memory film MEM. In this configuration, each of the conductive layers WL1, WL2, and WL3 functions as a word line. However, there are cases in which portions of lowermost and uppermost conductive layers of the plurality of conductive layers WL1, WL2, and WL3 which face the memory pillar MP function as selection transistors. Therefore, for example, the uppermost conductive layer WL3 in the third multi-layered body LM3 may function as a drain-side selection gate line SGD.

A plug PG is provided on the memory pillar MP. The plug PG penetrates the insulating layer 42 and is connected to an upper wiring ML. The upper wiring ML is connected to a transistor Tr formed on a substrate SB1 such as a silicon wafer through a via V. Such an upper wiring ML, a via V, a transistor Tr, and the like are covered with the insulating layer 50 such as silicon oxide, and control the memory cells as a peripheral circuit portion PER. Furthermore, in the description of FIG. 3 and subsequent figures, illustration of the peripheral circuit portion PER may be omitted for convenience.

The plate-shaped part STL penetrates the insulating layers 41 and 43, the third multi-layered body LM3, the insulating layers 31 to 33, the second multi-layered body LM2, the insulating layers 31 to 33, and the first multi-layered body LM1 in the Z direction and terminates within the source line SL.

Specifically, the plate-shaped part STL extends in the X direction and penetrates the first multi-layered body LM1, the insulating layers 31 to 33, the second multi-layered body LM2, the insulating layers 31 to 33, the third multi-layered body LM3, and the insulating layers 41 and 42 in the Z direction. In the following description, in a case in which the staircase-side plate-shaped part STLa and the bridge-side plate-shaped part STLb needs to be distinguished from each other in the plate-shaped part STL, they will be denoted as the staircase-side plate-shaped part STLa or the bridge-side plate-shaped part STLb.

In the plate-shaped part STL, the conductive portion EC containing a conductive material and the liner layer LL are formed in that order from the inside. For example, a metal containing tungsten W may be employed as a conductive material. Instead of a conductive material, a semiconductor material may also be used. For example, the plate-shaped part STL may contain silicon Si or germanium Ge. Alternatively, the plate-shaped part STL may be formed of an insulating material such as an oxide or nitride, such as silicon oxide SiO₂ or silicon nitride SiN. The liner layer LL may be formed of an insulating material such as silicon oxide SiO₂ or silicon nitride SiN. In a case in which the plate-shaped part STL is formed only of an insulating material, a portion corresponding to the conductive portion EC and the liner layer LL may be integrally formed of a single insulating material. Also, the plate-shaped part STL may have the same film configuration as the columnar portion HR to be described later.

As shown in FIG. 1, the plate-shaped parts STL extending in the X direction are formed intermittently in the X direction. In the staircase region SA, the plate-shaped part STL has intermittent portions 9 at predetermined intervals in the X direction. The support column parts 10 are formed to fill all of these intermittent portions 9. The support column part 10 is formed of, for example, silicon oxide. In the cell array region CA, the intermittent portion 9 is not present in the plate-shaped part STL. As shown in FIG. 1, block portions STB are periodically formed on the plate-shaped part STL. The block portion STB may be formed of an insulating material such as an oxide, a nitride, or the like such as, for example, silicon oxide SiO₂ or silicon nitride SiN.

Similarly to the plate-shaped part STL, the support column part 10 penetrates the insulating layers 41 and 43, the third multi-layered body LM3, the insulating layers 31 to 33, the second multi-layered body LM2, the insulating layers 31 to 33, and the first multi-layered body LM1 in the Z direction and terminates on the source line SL.

The support column part 10 formed in the Z direction along the plate-shaped part STL are denoted as a first support column part 10A, a second support column part 10B, and a third support column part 10C in order from the bottom.

The first support column part 10A is a support column part penetrating the first multi-layered body LM1. The second support column part 10B is a support column part penetrating the second multi-layered body LM2. The third support column part 10C is a support column part penetrating the third multi-layered body LM3. The support column part 10 contains an insulating material such as an oxide, a nitride, or the like such as, for example, silicon oxide SiO₂ or silicon nitride SiN. Also, for example, the same materials as those of the core layer CORE, the channel layer CHN, the memory film MEM, and the cap layer CAP may be filled into the support column part 10. The support column part 10 may have the same layered structure as the memory pillar MP. Also, the support column part 10 may have the same film configuration as the columnar portion HR to be described later. Alternatively, the support column part 10 may have the same film configuration as the plate-shaped part STL described above.

As shown in FIGS. 3 and 4, a first staircase portion SR1, a second staircase portion SR2, a third staircase portion SR3, the contacts CC, and the columnar portion HR are formed in the staircase region SA.

The first staircase portion SR1, the second staircase portion SR2, and the third staircase portion SR3 are formed by processing the first multi-layered body LM1, the second multi-layered body LM2, and the third multi-layered body LM3 into a staircase shape, respectively. Specifically, as shown in FIG. 3, the first staircase portion SR1 is included in the first multi-layered body LM1. The plurality of conductive layers WL1 are processed into a staircase shape extending in the X direction. As shown in FIG. 4, the second staircase portion SR2 is included in the second multi-layered body LM2. The plurality of conductive layers WL2 are processed into a staircase shape that is continuous with the second staircase portion SR2 in the X direction.

Also, in FIGS. 3 and 4, illustration of the third staircase portion SR3 is omitted. The third staircase portion SR3 is included in the third multi-layered body LM3. The plurality of conductive layers WL3 are processed into a staircase shape that is continuous with the third staircase portion SR3 in the X direction.

In FIG. 3, a lowermost step of the first staircase portion SR1, that is, the lowermost conductive layer WL1 of the first multi-layered body LM1, indicates a portion that is processed into a staircase shape. That is, in FIG. 3, the first staircase portion SR1 extends toward the front side of the page. Also, dummy staircase portions are formed on both sides in the Y direction of the first staircase portion SR1 extending in the X direction. These dummy staircase portions are staircases that are formed together when the first staircase portion SR1 is formed. The dummy staircase portions do not have a function of electrically extracting each conductive layers WL1 as in the first staircase portion SR1.

In FIG. 4, a lowermost step of the third staircase portion SR3, that is, the lowermost conductive layer WL3 of the third multi-layered body LM3, is processed into a staircase shape. That is, in FIG. 4, the third staircase portion SR3 also extends toward the front side of the page. Also, dummy staircase portions that do not have a function as the third staircase portion SR3 are formed on both sides in the Y direction of the third staircase portion SR3 extending in the X direction. Similarly, the second staircase portion SR2 also extends toward the front side of the page in the same way as the third staircase portion SR3, but is not shown in FIG. 4.

At a height position of the first multi-layered body LM1, the first staircase portion SR1 is covered with an insulating layer 34. The insulating layers 31 to 33 are formed on the insulating layer 34. The insulating layer 34 is, for example, a silicon oxide layer. Therefore, the insulating layers 31 to 34 are substantially integrated.

In the following description, among these, the insulating layers 31, 32, and 34 may be collectively referred to as a first interlayer-insulating film 30. As shown in FIG. 4, the second staircase portion SR2 is also covered with the insulating layer 34. The insulating layers 31 to 33 are formed on the insulating layer 34. In FIG. 4, illustration of the second staircase portion SR2 is omitted.

At a height position of the third multi-layered body LM3, the third staircase portion SR3 is covered with the insulating layer 43. The insulating layers 41 and 42 are formed on the insulating layer 43. The insulating layer 43 is, for example, a silicon oxide layer. Therefore, the insulating layers 41 to 43 are substantially integrated. In the following description, the insulating layers 41 to 43 may be collectively referred to as the third interlayer-insulating film 40. In FIG. 4, an upper side of the third multi-layered body LM3 is not shown in the drawings.

A part of the plurality of contacts CC penetrate the third interlayer-insulating film 40, a second interlayer-insulating film 30, and a first interlayer-insulating film 30 and are respectively connected to the conductive layers WL1 that form the plurality of step portions in the first staircase portion SR1. Another part of the plurality of contacts CC penetrate the third interlayer-insulating film 40 and the second interlayer-insulating film 30 and are respectively connected to the conductive layers WL2 that form the plurality of step portions in the second staircase portion SR2. Also, the remaining part of the plurality of contacts CC penetrate the third interlayer-insulating film 40 and are respectively connected to the conductive layers WL3 that form the plurality of step portions in the third staircase portion SR3.

In FIGS. 3 and 4, each of the contacts CC connected to the lowermost step of the first staircase portion SR1 or the lowermost step of the third staircase portion SR3 is shown. The contacts CC are connected to upper wirings (not shown in the drawings) in FIGS. 3 and 4. Therefore, the contact CC corresponding to any of the conductive layers WL1, WL2, and WL3 is electrically extracted.

The columnar portion HR penetrates the insulating layer 43, the third multi-layered body LM3, the insulating layers 31 to 33, the second multi-layered body LM2, the insulating layers 31 to 33, and the first multi-layered body LM1 in the Z direction, and terminates within the source line SL. In the embodiment, for example, the same materials as those of the core layer CORE, the channel layer CHN, the memory film MEM, and the cap layer CAP are filled in a hole of the columnar portion HR. The columnar portion HR has a layered structure similar to that of the memory pillar MP, but does not contribute to a function of the semiconductor storage device 1. When a sacrificial layer to be described later is replaced with a conductive layer in a multi-layered body (to be described later) in which the sacrificial layer and the insulating layer are stacked to form the first multi-layered body LM1, the second multi-layered body LM2, and the third multi-layered body LM3, the columnar portion HR has a function of supporting configurations of the multi-layered bodies. Also, the columnar portion HR can be denoted as a first columnar portion HR1, a second columnar portion HR2, and a third columnar portion HR3 in order from a side closer to the electrode film EL.

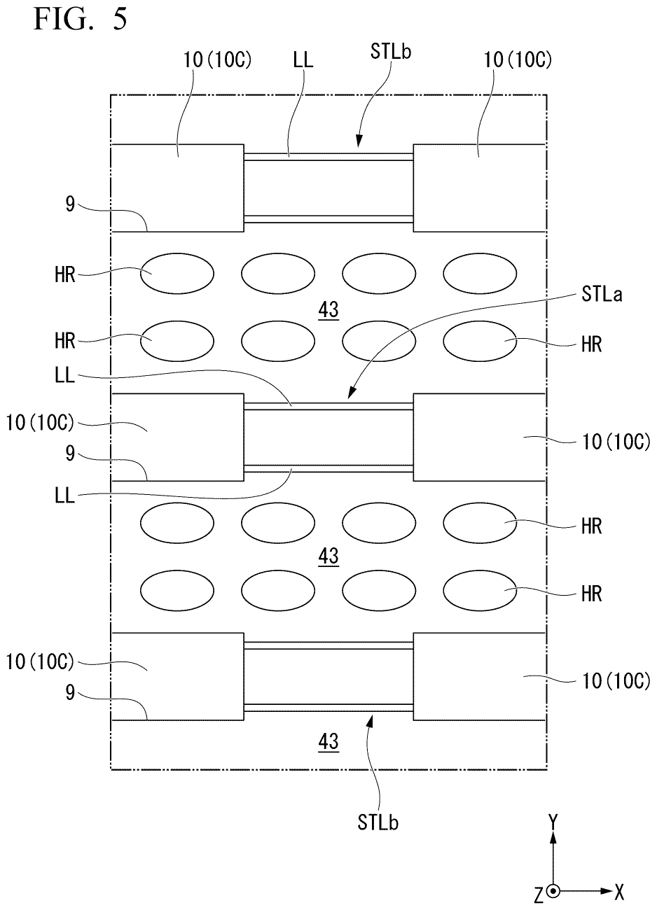

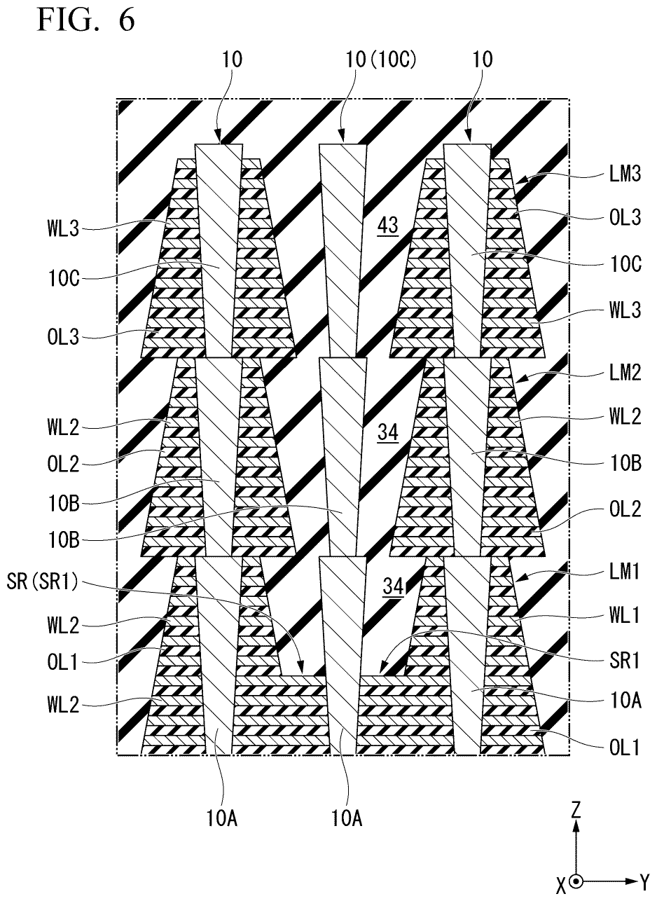

FIG. 5 shows a schematic configuration in a top view of the staircase region SA shown in FIG. 1. FIG. 6 shows a disposition example of the first multi-layered body LM1, the second multi-layered body LM2, and the third multi-layered body LM3, whose cross-sectional configurations are shown in FIGS. 3 and 4. Furthermore, FIG. 6 schematically shows a disposition example of the support column parts 10 disposed to penetrate the first multi-layered body LM1, the second multi-layered body LM2, and the third multi-layered body LM3 in the Z direction.

The top view shown in FIG. 5 shows a planar layout of the plate-shaped part STL and the third support column part 10C, and a planar layout of the columnar portion HR formed between the plate-shaped parts STL adjacent in the Y direction. In FIG. 5, the contacts CC shown in FIG. 1 are omitted. In FIG. 5, only a part of the planar layout of the plate-shaped part STL, the third support column part 10C, and the columnar portion HR is shown.

In the cross section shown in FIG. 6, a schematic configuration of the first multi-layered body LM1, the second multi-layered body LM2, the third multi-layered body LM3, and the first staircase portion SR1 is shown. FIG. 6 shows a disposition relationship between the dummy staircase portions formed on both sides of the staircase portion SR in the Y direction, and the first support column part 10A, the second support column part 10B, and the third support column part 10C which penetrate the dummy staircase portion in the Z direction. Furthermore, in FIG. 6, illustration of the interlayer-insulating films 30, 30, and 40 provided separately from the first multi-layered body LM1, the second multi-layered body LM2, and the third multi-layered body LM3 are omitted. Therefore, FIG. 6 is a simplified view. In FIG. 6, regarding the first staircase portion SR1 formed in the first multi-layered body LM1, only one step surface position near a center of a height in the Z directional of the first staircase portion SR1 is shown.

As shown in FIGS. 1 to 6, the semiconductor storage device 1 according to the first embodiment includes the support column part 10. The support column part 10 extends to fill the intermittent portions 9 in the staircase-side plate-shaped part STLa and the bridge-side plate-shaped part STLb in both the staircase-side plate-shaped part STLa and the bridge-side plate-shaped part STLb. The intermittent portion 9 and the support column part 10 are formed to penetrate the third multi-layered body LM3, the second multi-layered body LM2, and the first multi-layered body LM1 in the Z direction.

In the semiconductor storage device 1 shown in FIG. 1, in order to form the first multi-layered body LM1, the second multi-layered body LM2, and the third multi-layered body LM3, it is necessary to manufacture an alternating and repeatedly stacked structure of the conductive layers WL and insulating layers OL. As one method of manufacturing the multi-layered structure, a method is employed in which sacrificial layers and insulating layers are alternately and repeatedly stacked, and then, in a subsequent process after the layers are stacked, a replacement process in which the sacrificial layers are replaced with conductive layers is performed to manufacture the multi-layered body.

When the replacement process is performed, the sacrificial layers of the multi-layered bodies that are to become the first multi-layered body LM1, the second multi-layered body LM2, and the third multi-layered body LM3 are removed using an etching solution, and after the sacrificial layers are removed, film formation of the conductive layers is performed.

A sacrificial layer formed in the multi-layered body that is to become the first multi-layered body LM1 can be referred to as a first sacrificial layer. A sacrificial layer formed in the multi-layered body that is to become the second multi-layered body LM2 can be referred to as a second sacrificial layer. A sacrificial layer formed in the multi-layered body that is to become the third multi-layered body LM3 can be referred to as a third sacrificial layer. In the staircase region SA, a flow path for supplying the etching solution for etching the sacrificial layer is a slit groove that has existed before formation of the staircase-side plate-shaped part STLa. The slit groove before the bridge-side plate-shaped part STLb is formed is used as the flow path for supplying the etching solution.

When the sacrificial layer is removed by the etching solution, a hollow portion is formed between the stacked insulating layers. Therefore, the insulating layer needs to be supported. At this time, the columnar portion HR serves as a support column for supporting the stacked insulating layers via the hollow portion. Here, the slit groove before the staircase-side plate-shaped part STLa is formed and the slit groove before the bridge-side plate-shaped part STLb is formed are typically filled with a material for forming the plate-shaped part after the replacement process is performed. By the filling of the material, the liner layer LL and the conductive portion EC are formed.

In the structure of the first embodiment, the support column part 10 is formed in advance before the staircase-side plate-shaped part STLa and the bridge-side plate-shaped part STLb are formed. The support column parts 10 are disposed intermittently in the X direction. Therefore, the slit groove is present between the support column parts 10 and 10 that are disposed apart from each other in the X direction. In the replacement process, processing of removing the sacrificial layer using an etching solution can be performed through the slit groove.

At a stage in which the sacrificial layer is removed in the replacement process, the support column part 10, in addition to the columnar portion HR, supports the multi-layered body of the insulating layers. After the sacrificial layer is removed, since the portion of the sacrificial layer becomes a hollow portion, a conductive layer can be formed by forming a conductive material in the hollow portion.

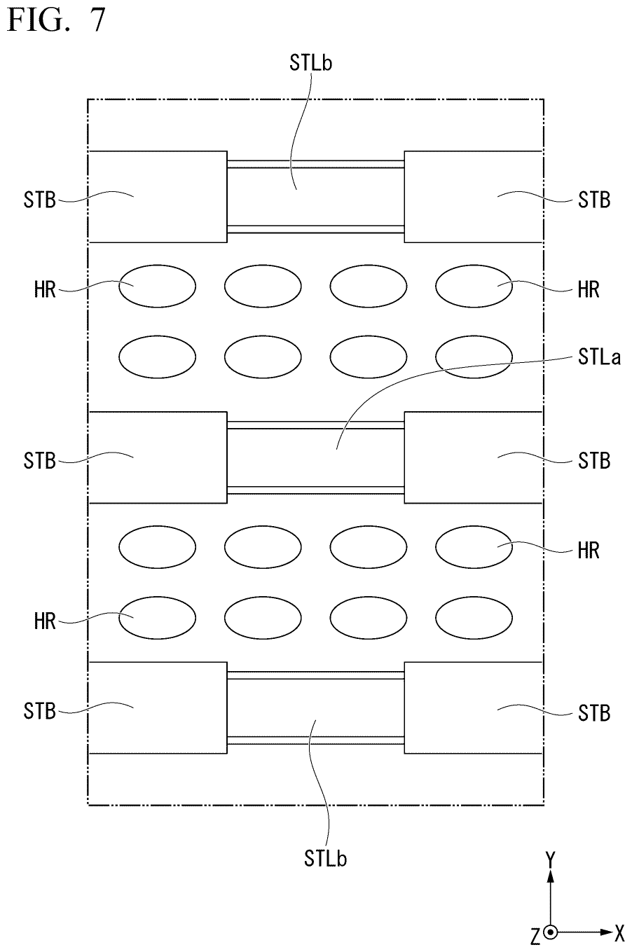

FIGS. 7 to 11 show a structure of comparative example 1. FIGS. 7 to 11 are views for explaining a situation in which deformation such as warping or distortion occurs in the staircase portion SR and the dummy staircase portions on the left and right sides thereof after the replacement process.

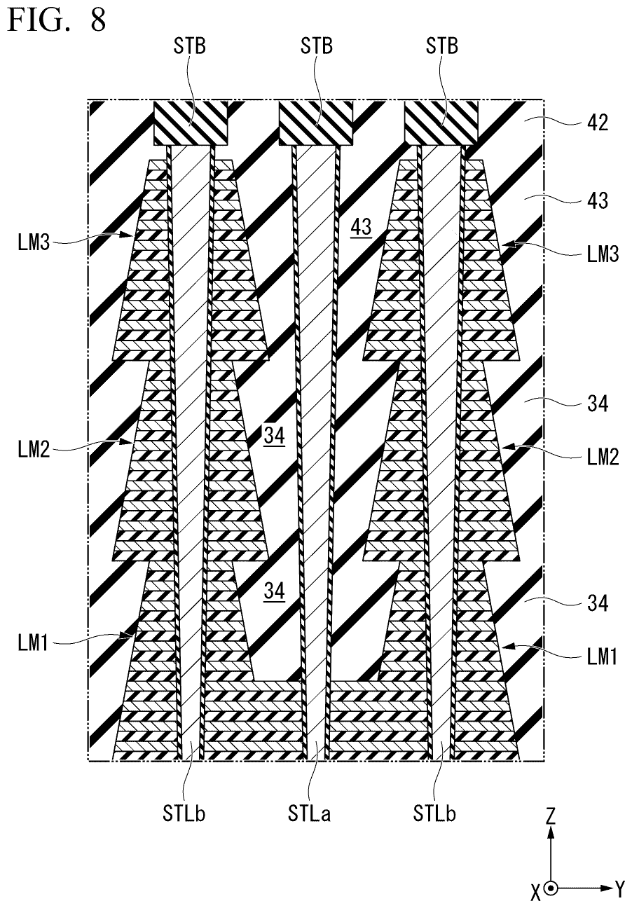

In the structure of comparison example 1 shown in FIGS. 7 and 8, even at a position in which the first support column part 10A is formed in the structure of the first embodiment, a material for forming the staircase-side plate-shaped part STLa of the first multi-layered body LM1 or a material for forming the bridge-side plate-shaped part STLb is filled.

Similarly, even at a position in which the second support column part 10B is formed, a material for forming the staircase-side plate-shaped part STLa of the second multi-layered body LM2 or a material for forming the bridge-side plate-shaped part STLb is filled. Similarly, even at a position in which the third support column part 10C is formed, a material for forming the staircase-side plate-shaped part STLa of the third multi-layered body LM3 or a material for forming the bridge-side plate-shaped part STLb is filled.

Furthermore, the block portion STB is formed in the insulating layer 42 on the third multi-layered body LM3 to be positioned on the staircase-side plate-shaped part STLa of the third multi-layered body LM3. The block portion STB is formed in the insulating layer 42 on the third multi-layered body LM3 to be positioned on the bridge-side plate-shaped part STLb of the third multi-layered body LM3. The block portion STB is formed of, for example, silicon oxide.

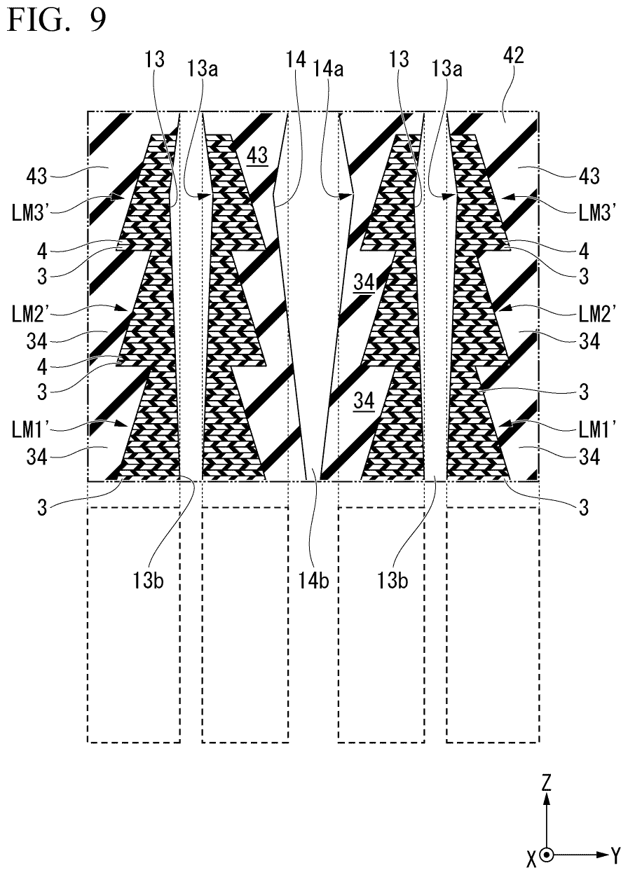

In the structure of comparative example 1 shown in FIGS. 7 and 8, there is a likelihood of deformation such as warping or distortion occurring in the staircase portion and the dummy staircase portion around the staircase portion as shown in FIGS. 9 to 11.

FIG. 9 shows a state before forming the first multi-layered body LM1, the second multi-layered body LM2, and the third multi-layered body LM3, in which a first precursor multi-layered body LM1′ is formed by stacking an insulating layer 3 and a sacrificial layer 4, a second precursor multi-layered body LM2′ is formed by stacking the insulating layer 3 and the sacrificial layer 4, and a third precursor multi-layered body LM3′ is formed by stacking the insulating layer 3 and the sacrificial layer 4. Peripheries of the first precursor multi-layered body LM1′, the second precursor multi-layered body LM2′, and the third precursor multi-layered body LM3′ are covered with the insulating layers 34, 34, and 43.

As an example, the insulating layer 3 can be formed of a silicon oxide layer. The sacrificial layer may be formed of a silicon nitride layer.

Thereafter, a slit groove 13 is formed to penetrate the first precursor multi-layered body LM1′, the second precursor multi-layered body LM2′, and the third precursor multi-layered body LM3′ by ion etching or the like. At the same time, a slit groove 14 is formed in the insulating layers 34, 34, and 43 between the left and right first precursor multi-layered body LM1′, second precursor multi-layered body LM2′, and third precursor multi-layered body LM3′ by ion etching or the like.

When the slit grooves 13 and 14 are formed by ion etching, a structure of a film forming the slit groove 13 is different from a structure of a film forming the slit groove 14. While the film around the slit groove 13 has a stacked structure of the insulating layer 3 and the sacrificial layer 4, the film around the slit groove 14 is formed only of the insulating layers 34, 34, and 43. Also, if ion etching is performed, due to a difference in etching selectivity or the like, bulging portions 13a and 14a with large inner diameters are formed on upper sides of the slit grooves 13 and 14, and reduced diameter portions 13b and 14b with small inner diameters are formed on lower end sides of the slit grooves 13 and 14. Also, in a case of the cross-sectional structure shown in FIG. 9, due to a difference in film types around the slit grooves 13 and 14, an inner diameter of the bulging portion 14a formed in the slit groove 14 is larger than an inner diameter of the bulging portion 13a formed in the slit groove 13.

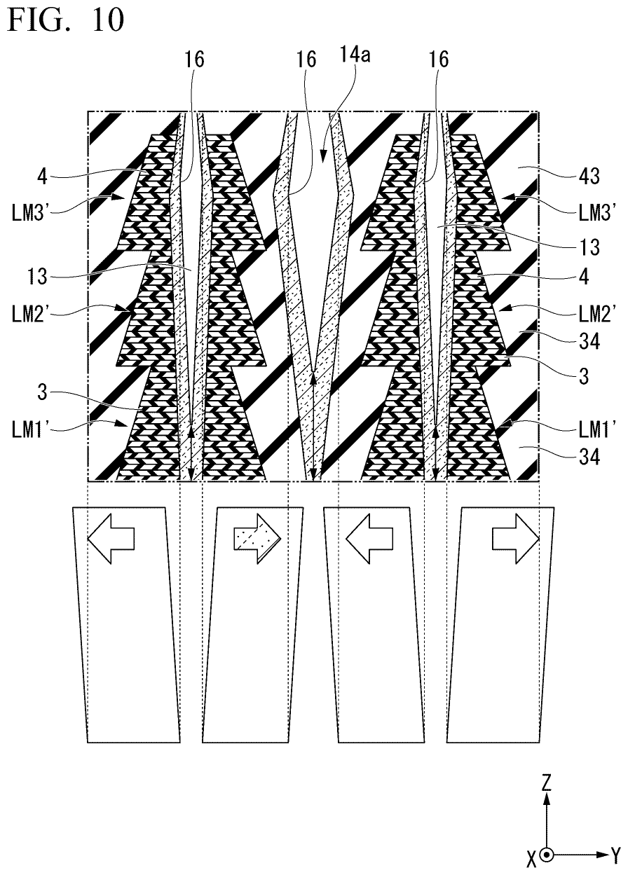

In the structure shown in FIG. 9, the inside of the slit grooves 13 and 14 is filled with a filling material 16 such as amorphous silicon. Then, as shown in FIG. 10, since lower end portions of the slit grooves 13 and 14 with smaller inner diameters are first closed, a tensile stress acts in a direction indicated by the arrows in FIG. 10 due to film shrinkage after film formation.

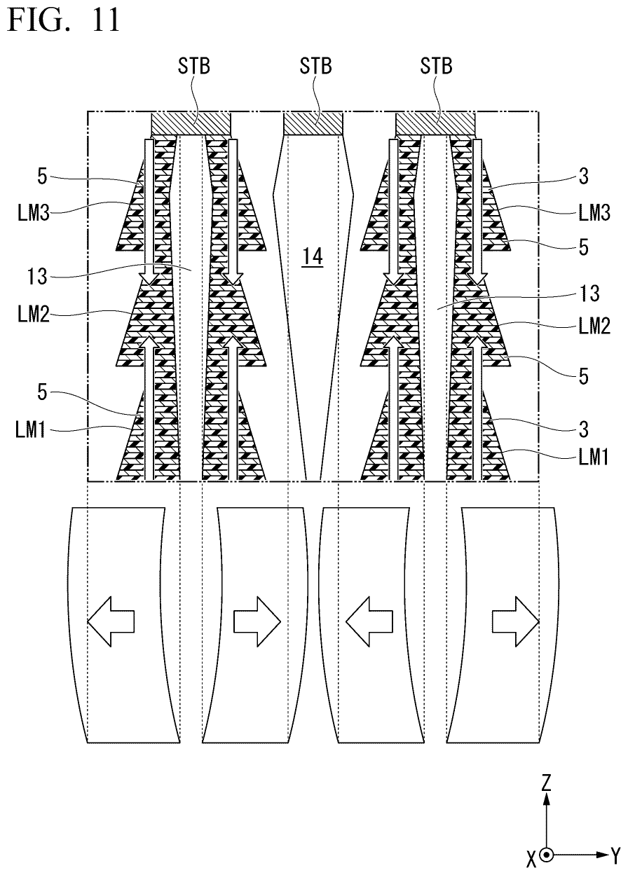

Next, as shown in FIG. 11, the block portions STB are formed on the insulating layer 42 on the third multi-layered body LM3 to be positioned intermittently in the X direction on the staircase-side plate-shaped part STLa and the bridge-side plate-shaped part STLb.

Thereafter, the filling material 16 filled in each of the slit grooves 13 and 14 is removed, and the sacrificial layer 4 is replaced with the conductive layer 5 by the replacement process. Therefore, the first precursor multi-layered body LM1′ becomes the first multi-layered body LM1. The second precursor multi-layered body LM2′ becomes the second multi-layered body LM2. The third precursor multi-layered body LM3′ becomes the third multi-layered body LM3.

After the replacement process, as indicated by the arrows in FIG. 11, the slit grooves 13 and 14 positioned below the block portions STB are constrained by the block portions STB. Here, a shrinkage stress of a conductive layer (tungsten film) 5 formed by the replacement process acts. Then, the stress acts on the first multi-layered body LM1, the second multi-layered body LM2, and the third multi-layered body LM3 in the directions indicated by the arrows. Therefore, as shown in a lower part of the cross-sectional view of FIG. 11, a phenomenon occurs in which the first multi-layered body LM1 to the third multi-layered body LM3 are deformed in an arc shape.

In a side view with the slit groove 13 as a center, a stress acts to deform the first multi-layered body LM1 to the third multi-layered body LM3 into a barrel shape. In a side view with the slit groove 14 as a center, a stress acts to deform the slit groove 14 so that a central side thereof in the Z direction is closed.

That is, deformation such as warping or distortion occurs in the multi-layered bodies such as the staircase portion and the dummy staircase portion present around the staircase portion.

As described above, deformation such as warping or distortion occurring in the multi-layered body described with reference to FIGS. 9 to 11 is unlikely to occur in the semiconductor storage device 1 according to the first embodiment described above.

As can be seen by comparing FIGS. 6 and 8, the structure of comparative example 1 has a structure in which the upper parts of the slit grooves 13 and 14 for forming the staircase-side plate-shaped part STLa or the bridge-side plate-shaped part STLb are simply constrained by the block portions STB.

In contrast, in the structure of the first embodiment, the first multi-layered body LM1, the second multi-layered body LM2, and the third multi-layered body LM3 are penetrated in the Z direction as shown in FIG. 6. Furthermore, in the structure of the first embodiment, the support column parts 10 disposed intermittently in the X direction are present as support columns as shown in FIG. 1.

The support column part 10 is present independently of the presence of the slit groove for forming the staircase-side plate-shaped part STLa or the bridge-side plate-shaped part STLb. Therefore, during the replacement process for forming the first multi-layered body LM1, the second multi-layered body LM2, and the third multi-layered body LM3, the support column part 10 functions as a support column that supports the first multi-layered body LM1, the second multi-layered body LM2, and the third multi-layered body LM3 to suppress deformation thereof.

Therefore, in the structure of the first embodiment, deformation such as warping or distortion is unlikely to occur in the multi-layered bodies such as the staircase portions SR of the first multi-layered body LM1, the second multi-layered body LM2, and the third multi-layered body LM3, and the dummy staircase portion around them. According to the structure of the first embodiment, it is possible to provide the semiconductor storage device 1 having the well-formed staircase portion SR and the surrounding structure thereof.

### Second Embodiment

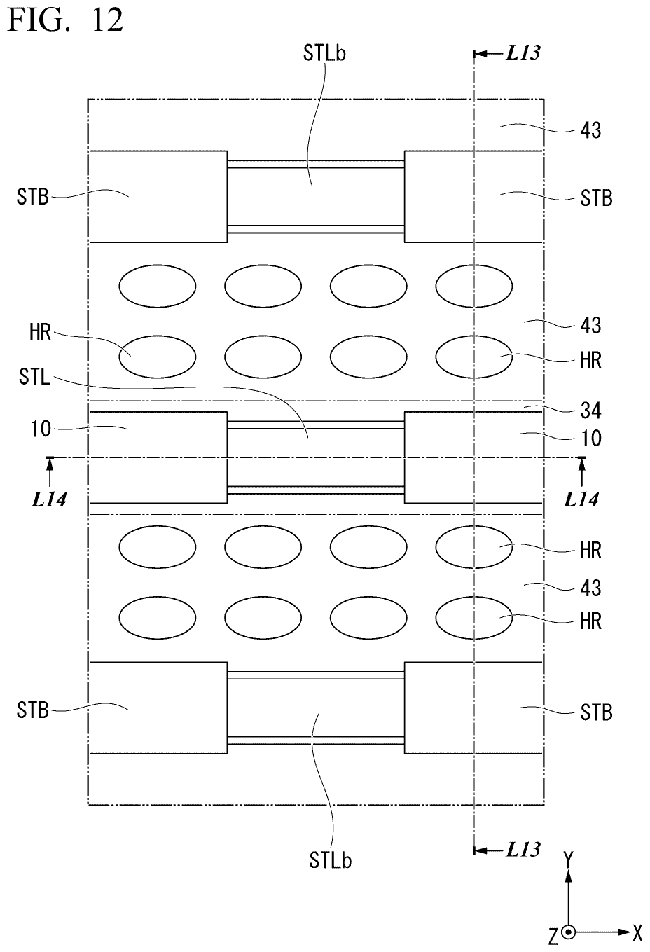

A configuration example of a semiconductor storage device according to a second embodiment will be described below with reference to FIGS. 12 to 14. The semiconductor storage device according to the embodiment has a cell array region CA and a staircase region SA similarly to the semiconductor storage device 1 according to the first embodiment. A configuration of the cell array region CA is the same as that of the first embodiment.

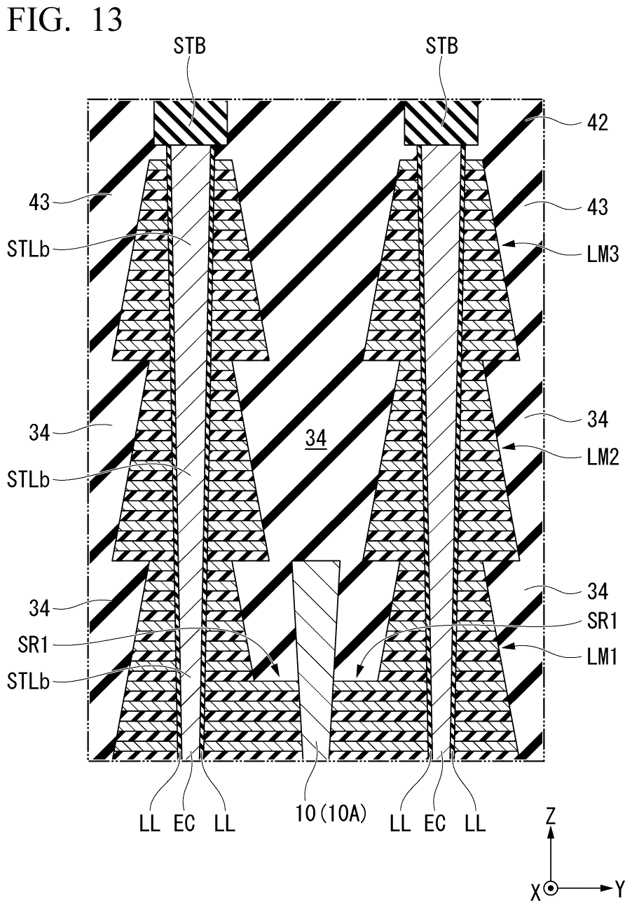

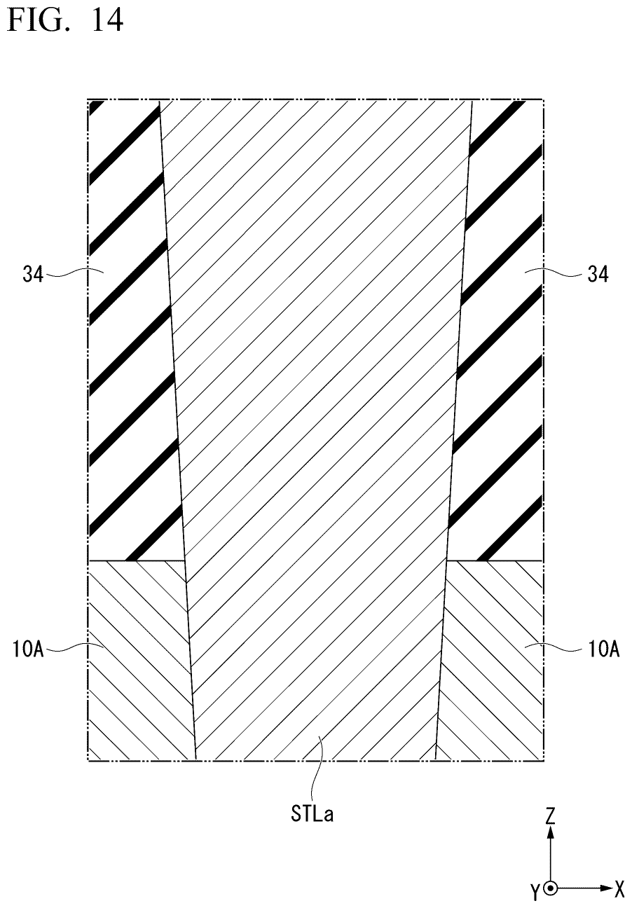

In the semiconductor storage device according to the second embodiment, a structure of the staircase region SA is partially different from that of the first embodiment. In the semiconductor storage device according to the second embodiment, FIG. 12 shows a schematic configuration of a planar layout corresponding to FIG. 5 in which the schematic configuration of the planar layout of the staircase region SA in the first embodiment is shown. Also, in correspondence with FIG. 6 which shows a schematic configuration of the cross-sectional structure of the first multi-layered body LM1 to the third multi-layered body LM3 in the first embodiment, in the second embodiment, FIG. 13 shows a part of a cross section along line L13-L13 in FIG. 12. FIG. 14 shows a part of a cross section along line L14-L14 in FIG. 12.

In the second embodiment, a configuration in which support column parts 10A are intermittently formed in a staircase-side plate-shaped part STLa that divides staircase portions SR formed in a first multi-layered body LM1 is the same as that in the first embodiment.

In the second embodiment, the support column part 10 is not formed in a bridge-side plate-shaped part STLb. Also, even the intermittent portion 9 is not formed in the bridge-side plate-shaped part STLb. Instead, the bridge-side plate-shaped part STLb of the first multi-layered body LM1 extends with a uniform structure in an X direction in the staircase region SA.

In a structure in which the first multi-layered body LM1, the second multi-layered body LM2, and the third multi-layered body LM3 are stacked as shown in FIG. 11, there is a likelihood that the third multi-layered body LM3 positioned on an upper layer side will suffer greatest deformation such as warping or distortion.

Therefore, when the support column parts 10A are formed intermittently in the X direction for the first multi-layered body LM1 positioned on a lower layer side as shown in FIG. 13, deformation such as warping or distortion of the staircase portion SR of the first multi-layered body LM1 and its surroundings can be suppressed.

Furthermore, in the second embodiment, a support column part 10B is not formed in the staircase-side plate-shaped part STLa of a second multi-layered body LM2. However, in the second embodiment, similarly to the first embodiment, the support column part 10B may be formed in the staircase-side plate-shaped part STLa of the second multi-layered body LM2. When the support column part 10B is provided in the staircase-side plate-shaped part STLa of the second multi-layered body LM2, deformation such as warping or distortion in the staircase portion SR of the second multi-layered body LM2 and a dummy staircase portion around the staircase portion SR can be suppressed.

Also, in the second embodiment, similarly to the first embodiment, a support column part 10C may be provided in the staircase-side plate-shaped part STLa of a third multi-layered body LM3. When the support column part 10C is provided in the staircase-side plate-shaped part STLa of the third multi-layered body LM3, deformation such as warping or distortion in the staircase portion SR of the third multi-layered body LM3 and the dummy staircase portion around the staircase portion SR can be suppressed.

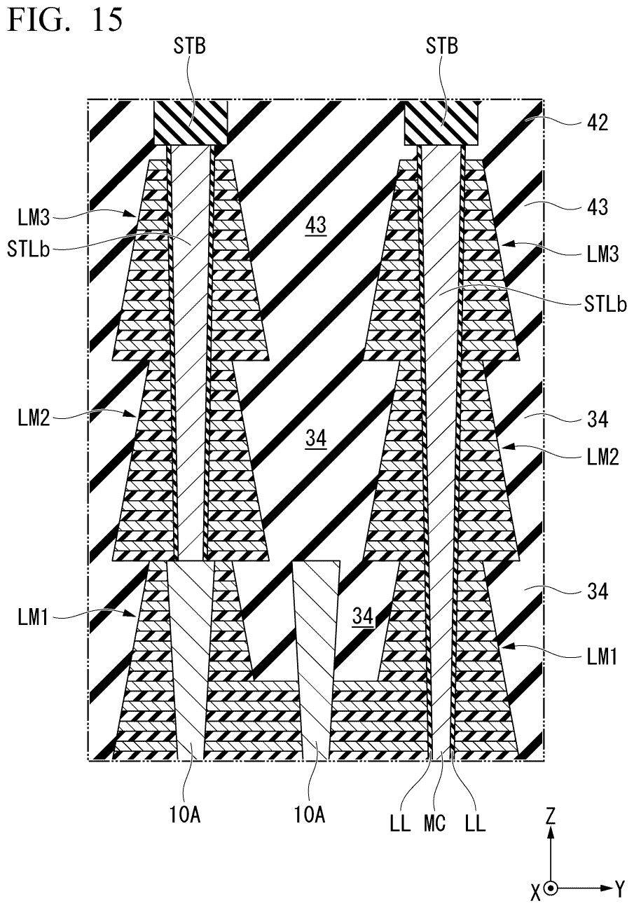

FIG. 15 shows a configuration example of the first multi-layered body LM1, the second multi-layered body LM2, and the third multi-layered body LM3 applied to a semiconductor storage device of a second comparative example.

In the semiconductor storage device of comparative example 2, the support column parts 10A are formed intermittently in the X direction in the staircase-side plate-shaped part STLa that divides the staircase portions SR formed in the first multi-layered body LM1. Also, the support portions 10A are formed intermittently in the X direction in one bridge-side plate-shaped parts STLb adjacent to the staircase-side plate-shaped part STLa that divides the stair portions SR. The other configurations are the same as those of the second embodiment shown in FIG. 13.

In the structure shown in FIG. 15, the support column part 10A is formed in the bridge-side plate-shaped part STLb of the first multi-layered body LM1, and the support column part 10B is not formed in the bridge-side plate-shaped part STLb of the second multi-layered body LM2 above the support column part 10A, but instead the bridge-side plate-shaped part STLb is formed over the entire region in the X direction. There is a problem in this structure.

In the first multi-layered body LM1 and the second multi-layered body LM2 in which a conductive layer WL and an insulating layer OL are stacked, there is a likelihood that problems may occur in a structure in which the first multi-layered body LM1 has the support column part 10A, and the second multi-layered body LM2 above it has only the bridge-side plate-shaped part STLb. For example, since the conductive layer WL is present in each of the multi-layered bodies, slit groove processing is necessary, but if the slit groove processing is not performed, there is a problem that deformation such as warping or distortion is likely to occur in the multi-layered body, causing a problem during the replacement process.

Also, when the slit groove processing is performed, there is a problem that forming the bridge-side plate-shaped part STLb of the second multi-layered body LM2 is not easy to implement because the slit groove processing cannot be stopped at the portion of the support column part 10A positioned below, resulting in damage to the support column part 10A.

### Manufacturing Method of First Embodiment

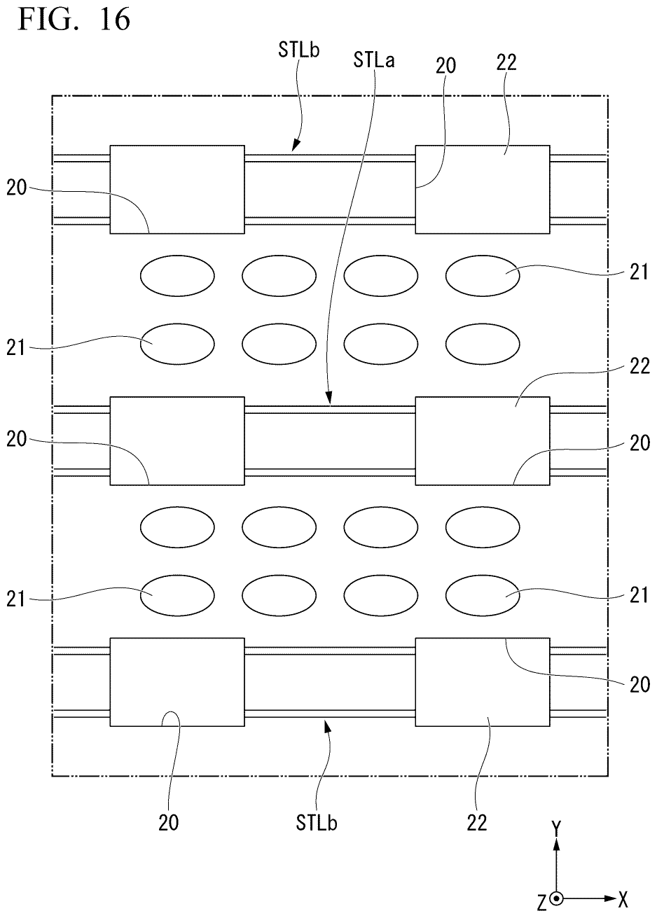

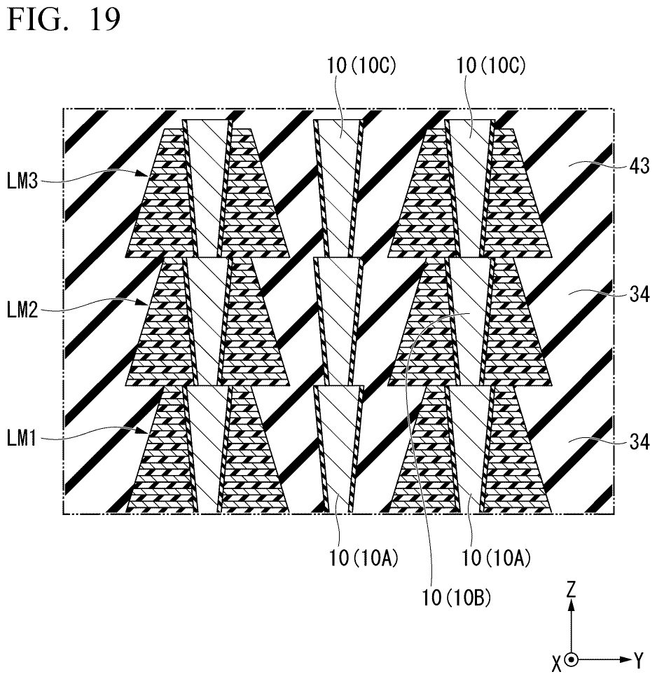

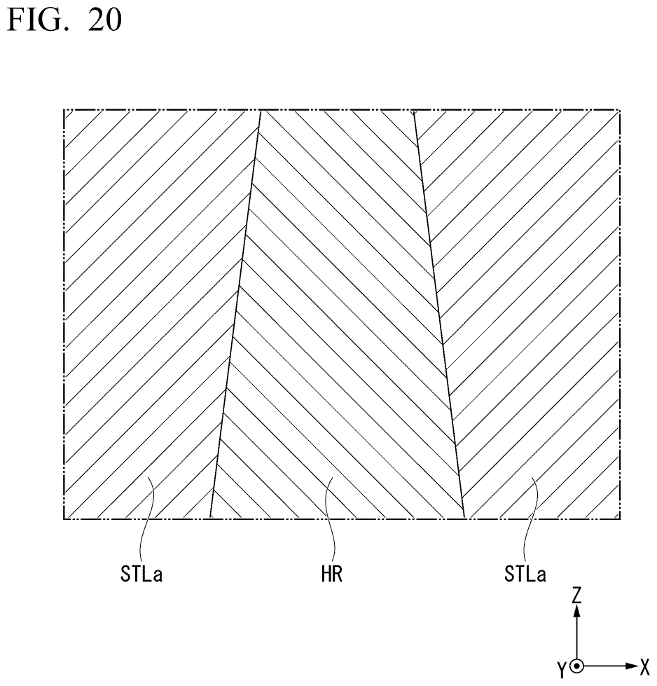

FIGS. 16 to 22 are views for explaining an example of a manufacturing method of the semiconductor storage device according to the first embodiment.

When the semiconductor storage device 1 is manufactured, as an example, the peripheral circuit portion PER covered with the insulating layer 50 is formed on the substrate SB1 (see FIG. 2) such as a silicon wafer. Another substrate (not shown in the drawings) on which the first multi-layered body LM1 to the third multi-layered body LM3 are formed is bonded to the substrate SB1, the another substrate is removed by polishing, thereby the structure shown in FIGS. 2 to 4 can be obtained. Here, the substrate SB1 may be referred to as a first substrate, and another substrate may be referred to as a second substrate.

First, the electrode film EL, the insulating layer 50, and the source line SL are formed on the another substrate. On the another substrate, the first precursor multi-layered body LM1′ serving as the basis for the first multi-layered body LM1, the second precursor multi-layered body LM2′ serving as the basis for the second multi-layered body LM2, and the third precursor multi-layered body LM3′ serving as the basis for the third multi-layered body LM3 are formed. The plate-shaped parts STLa and STLb are formed in each precursor multi-layered body, and holes are formed at necessary positions in each precursor multi-layered body. Therefore, a state shown in the top view of FIG. 16 is obtained.

In the first precursor multi-layered body LM1′, in a preceding process (not shown in the drawings), the staircase portion is formed by a series of processes including forming a mask using photoresist, etching using the mask, slimming the mask, and etching using the slimmed mask.

The first precursor multi-layered body LM1′ serving as the basis for the first multi-layered body LM1 is a multi-layered body in which insulating layers and sacrificial layers are alternately stacked one by one.

The first interlayer-insulating film 30 and the second precursor multi-layered body LM2′ are formed on the first precursor multi-layered body LM1′ to form a staircase portion. The second interlayer-insulating film 30 and the third precursor multi-layered body LM3′ are formed on the second precursor multi-layered body LM2′ to form a staircase portion. The third interlayer-insulating film 40 is formed.

The second precursor multi-layered body LM2′ serving as the basis for the second multi-layered body LM2 is a multi-layered body in which insulating layers and sacrificial layers are alternately stacked one by one. The third precursor multi-layered body LM3′ serving as the basis for the third multi-layered body LM3 is a multi-layered body in which insulating layers and sacrificial layers are alternately stacked one by one.

In the first precursor multi-layered body LM1′, the staircase portion is formed at a required position and is covered with the insulating layer 34 and the first interlayer-insulating film 30. In the second precursor multi-layered body LM2′ to be fabricated in a later process, the staircase portion is formed at a required position and is covered with the insulating layer 34 and the second interlayer-insulating film 30. In the third precursor multi-layered body LM3′ to be fabricated in a later process, the staircase portion is formed at a required position and is covered with the third interlayer-insulating film 40 including the insulating layer 43.

FIG. 16 is a partial top view of the staircase region SA. Along positions in which the staircase-side plate-shaped part STLa and the bridge-side plate-shaped part STLb are formed, a support column part hole (first opening) 20 for forming the support column part 10 and a columnar portion hole 21 for forming the columnar portion HR are formed at predetermined intervals. Therefore, the state shown in FIG. 16 is obtained. FIG. 16 shows the support column part holes 20 disposed intermittently in the X direction along the positions at which the staircase-side plate-shaped part STLa and the bridge-side plate-shaped part STLb are formed.

The positions of the support column part holes 20 formed here correspond to the positions at which the support column parts 10 shown in FIG. 1 are present. A width of the support column part hole 20 in the Y direction is made slightly larger than widths of the staircase-side plate-shaped part STLa and the bridge-side plate-shaped part STLb in the Y direction. The support column part hole 20 and the columnar portion hole 21 for forming the columnar portion HR may be formed simultaneously in each process. For example, after the first precursor multi-layered body is formed, the first support column part hole 20 and the first columnar portion hole 21 may be formed by the same etching.

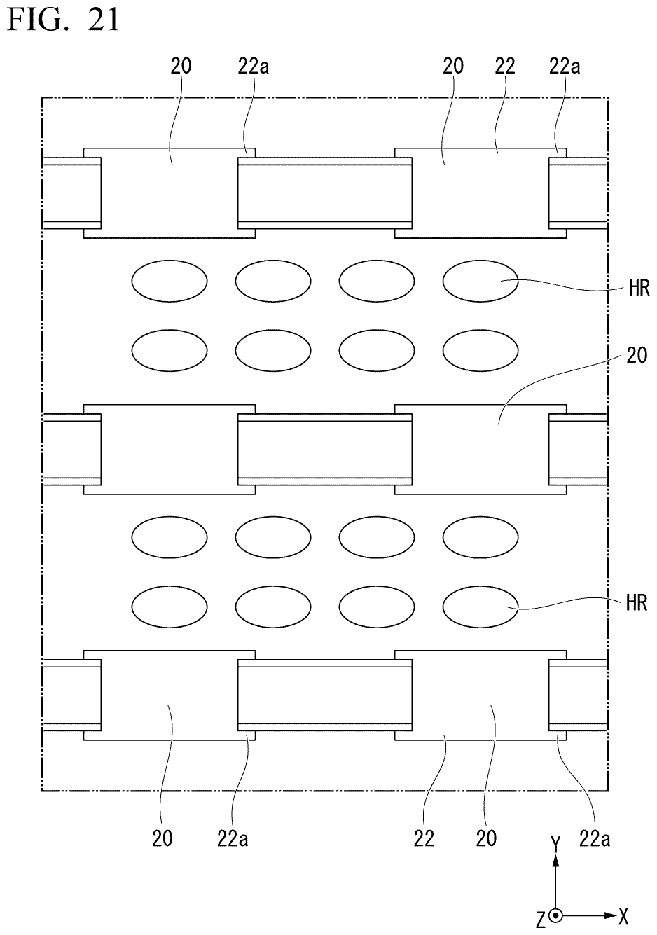

A width of the support column part hole 20 in the Y direction is slightly larger than a width of the staircase-side plate-shaped part STLa in the Y direction. Therefore, extending portions 22 extending outward from ends of the staircase-side plate-shaped part STLa in the Y direction are formed on both sides of the support column part hole 20 in the Y direction. As shown in FIG. 21, extending portions 22a extending outward from ends of the bridge-side plate-shaped part STLb in the X direction are formed on both sides of the support column part hole 20 in the X direction.

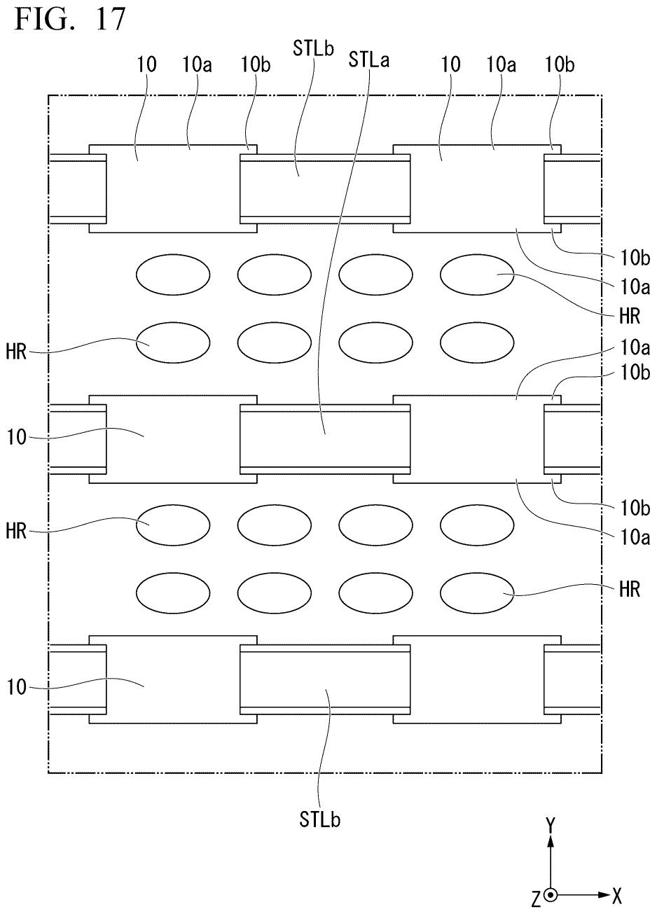

From the state shown in FIG. 21, the support column part 10 is formed in the support column part hole 20, a slit groove is formed, and the columnar portion HR is formed in the columnar portion hole 21. This state is shown in FIG. 17. The support column part 10 can be formed by filling the support column part hole 20 with an insulating material such as silicon oxide. When the columnar portion HR is formed simultaneously with the film formation for forming the memory pillar MP, the columnar portion HR has a core layer, a channel layer, and a memory film that are concentrically formed from the center to the outside. In FIGS. 16, 17, and 21, the columnar portion HR is shown as a simple elliptical shape for the sake of simplifying the illustration. The columnar portion HR may be formed simultaneously with the film formation for forming the memory pillar MP when the support column part hole 20 is filled with an insulating film. When the insulating film is filled into the support column part hole 20, it may be formed simultaneously with the filling of the insulating film into the columnar portion HR. Also, the material filled into the support column part 10 and the columnar portion HR may include a metal such as tungsten, or a semiconductor such as silicon or germanium.

When the support column part 10 is formed, the support column part hole 20 has the extending portion 22. Therefore, extending portions 10a that extend outward in the Y direction further than both sides in the Y direction of the staircase-side plate-shaped part STLa or the bridge-side plate-shaped part STLb are formed on both sides of the support column part 10 in the Y direction.

Also, protruding portions 10b that extend in the X direction by a predetermined length along an outer side of the staircase-side plate-shaped part STLa or the outer side of the bridge-side plate-shaped part STLb are formed at both ends of the extending portion 10a in the X direction. The support column part 10, by having the extending portion 10a and the protruding portion 10b, is formed in an H shape in a plan view as shown in FIG. 17.

When realizing the multi-layered structure of the first multi-layered body LM1, the second multi-layered body LM2, and the third multi-layered body LM3 as in the first embodiment, a replacement process for fabricating it by the following procedure can be selected as an example.

After forming the first precursor multi-layered body LM1′ in which the sacrificial layers and the insulating layers are stacked, the insulating layers 31 and 34 are formed. Slit grooves are formed at planned formation positions of the staircase-side plate-shaped part STLa and the bridge-side plate-shaped part STLb. The slit grooves are filled with a filling material such as amorphous silicon.

When the slit grooves are formed, for example, at least two slit grooves apart from each other with the support column part 10 interposed therebetween in the X direction are formed. Of these slit grooves, one slit groove may be referred to as a first slit and the other slit groove may be referred to as a second slit.

Also, when the filling material is filled into the first slit and the second slit to form a plate-shaped part, it can be said that a first plate-shaped part is formed in the first slit and a second plate-shaped part is formed in the second slit.

After forming the second precursor multi-layered body LM2′ in which the sacrificial layers and the insulating layers are stacked, the insulating layers 31 and 34 are formed. Slit grooves are formed at planned formation positions of the staircase-side plate-shaped part STLa and the bridge-side plate-shaped part STLb. The slit grooves are filled with a filling material such as amorphous silicon.

After forming the third precursor multi-layered body LM3′ in which the sacrificial layers and the insulating layers are stacked, the insulating layers 41 and 43 are formed. Slit grooves are formed at planned formation positions of the staircase-side plate-shaped part STLa and the bridge-side plate-shaped part STLb. The slit grooves are filled with a filling material such as amorphous silicon.

When formed by such a method, a cross section of the staircase-side plate-shaped part STLa and the bridge-side plate-shaped part STLb exhibits a three-layered structure. That is, it appears as if three tapered shapes, whose width increases toward the top, are stacked similarly to the columnar portion HR.

Alternatively, in the staircase-side plate-shaped part STLa and the bridge-side plate-shaped part STLb, the first precursor multi-layered body, the second precursor multi-layered body, and the third precursor multi-layered body are formed. Thereafter, a slit groove that penetrates all of the precursor multi-layered bodies at once may be formed. For example, the staircase-side plate-shaped part STLa and the bridge-side plate-shaped part STLb shown in FIGS. 3 and 4 are formed by a method of penetrating all of the precursor multi-layered bodies LM1′, LM2′, and LM3′ at once.

The amorphous silicon filled in each of the slit grooves of the first precursor multi-layered body LM1′, the second precursor multi-layered body LM2′, and the third precursor multi-layered body LM3′ is removed by etching. Therefore, it is possible to form the slit grooves penetrating the first precursor multi-layered body LM1′ to the third precursor multi-layered body LM3′.

Thereafter, the sacrificial layers of the first precursor multi-layered body LM1′, the second precursor multi-layered body LM2′, and the third precursor multi-layered body LM3′ are removed through the slit grooves to hollow portions. A conductive layer formed of tungsten or the like is deposited in the hollow portion. Therefore, it is possible to form a stacked structure of the first multi-layered body LM1, the second multi-layered body LM2, and the third multi-layered body LM3 in which conductive layers and insulating layers are stacked.

Furthermore, in order to fabricate the columnar portion HR, a hole is formed together with formation of the slit groove at a stage in which the first precursor multi-layered body LM1′ and the insulating layers 31 and 34 have been fabricated. This hole is filled with a filling material such as amorphous carbon.

Next, at a stage in which the second precursor multi-layered body LM2′ and the insulating layers 31 and 34 have been fabricated, a hole is formed together with formation of the slit groove. This hole is filled with a filling material such as amorphous carbon.

Next, at a stage in which the third precursor multi-layered body LM3′ and the insulating layers 41 and 43 have been fabricated, a hole is formed together with formation of the slit groove. This hole is filled with a filling material such as amorphous carbon.

Alternatively, the first precursor multi-layered body LM1′, the second precursor multi-layered body LM2′, and the third precursor multi-layered body LM3′ are formed. Thereafter, the hole 21 for the columnar portion HR penetrating all of the precursor multi-layered bodies at once may be formed.

The support column part 10 may also be formed in the same manner as when the columnar portion HR is formed. That is, the support column part 10 may be formed in each of the multi-layered bodies of the first precursor multi-layered body LM1′, the second precursor multi-layered body LM2′, and the third precursor multi-layered body LM3′.

Alternatively, the first precursor multi-layered body LM1′, the second precursor multi-layered body LM2′, and the third precursor multi-layered body LM3′ are formed. Thereafter, the hole 20 for forming the support column part 10 that penetrate all of the precursor multi-layered bodies at once may be formed.

After the first precursor multi-layered body LM1′, the second precursor multi-layered body LM2′, and the third precursor multi-layered body LM3′ are stacked, the amorphous carbon is removed by ashing or the like. Therefore, it is possible to form a hole penetrating the first precursor multi-layered body LM1′, the second precursor multi-layered body LM2′, and the third precursor multi-layered body LM3′. When the hole is filled with the core layer CORE, the channel layer CHN, the memory film MEM, and the like that are used in forming the memory pillar MP described above, the columnar portion HR can be formed. When the columnar portion HR is formed, the support column part 10 may also be formed in the same manner.

As described above, FIG. 17 shows a state in which the support column part 10 is formed in the support column part hole 20 shown in FIG. 16, and the columnar portion HR is formed in the columnar portion hole 21. FIG. 17 shows a state in which the staircase-side plate-shaped part STLa and the bridge-side plate-shaped part STLb have also been formed.

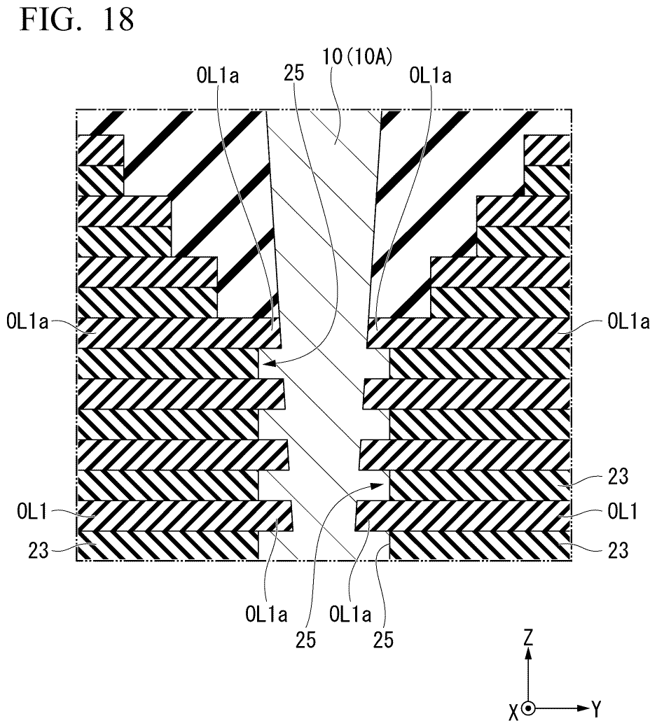

FIG. 18 shows a YZ cross section of a region in the first precursor multi-layered body LM1′ that is sandwiched between the bridge-side plate-shaped part STLb in which the support column part 10 is formed and the staircase-side plate-shaped part STLa in which the support column part 10 is formed. As shown in FIG. 18, the multi-layered structure of the first precursor multi-layered body LM1′ positioned on both sides of the support column part 10 in the Y direction is a stacked structure of the insulating layers OL1 and a sacrificial layers 23.

In the structure and manufacturing method of the first embodiment, in the multi-layered structure of the insulating layers OL1 and the sacrificial layers 23 disposed on a lower layer side of the first precursor multi-layered body LM1′, it is preferable to form a cross-sectional uneven structure over a plurality of layers in the Z direction on a bottom part side of the support column part 10.

As an example, in the cross section shown in FIG. 18, an end portion (extension part) OL1a of the insulating layer OL1 on the support column part 10 side is formed to be slightly longer than an end portion 23a of the sacrificial layer 23 on the support column part 10 side. For example, the end portion (extension part) OL1a of the insulating layer OL1 on the support column part 10 side protrudes to a center side of the support column part 10 further than the end portion 23a of the sacrificial layer 23 on the support column part 10 side. Therefore, a recessed portion 25 is formed between the upper and lower extension parts OL1a and OL1a adjacent in the Z direction. Therefore, the end portion 23a of the sacrificial layer 23 is disposed on a bottom part side of the recessed portion 25.

For example, after the support column part hole 20 is opened, a part of the sacrificial layer 23 is removed from the opening by etching. Thereafter, the support column part 10 shown in FIG. 18 can be formed by forming an insulating film or the like in the support column part hole 20 (first opening).

The first multi-layered body LM1 is obtained by employing the structure shown in FIG. 18, removing the sacrificial layer 23 of the first precursor multi-layered body LM1′ in the replacement process, forming a hollow portion, and forming the conductive layer WL in the hollow portion.

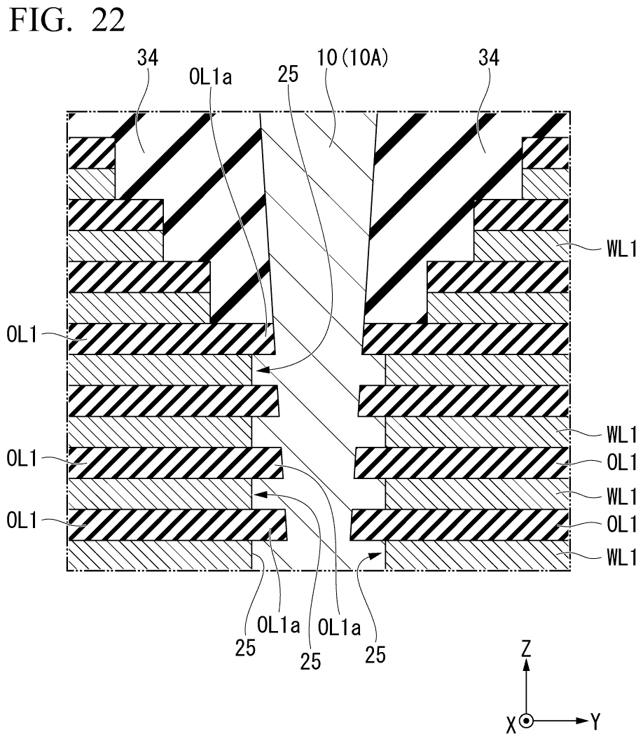

FIG. 22 shows a YZ cross section of the first multi-layered body LM1 fabricated corresponding to the first precursor multi-layered body LM1′ shown in FIG. 18.

Prior to the replacement process, the first precursor multi-layered body LM1′, the second precursor multi-layered body LM2′, and the third precursor multi-layered body LM3′ were formed, and after each of the multi-layered bodies was formed, amorphous silicon was filled into each slit groove to fill the slit grooves. In the replacement process, the amorphous silicon that has filled the slit grooves of the first precursor multi-layered body LM1′, the second precursor multi-layered body LM2′, and the third precursor multi-layered body LM3′ is removed to allow the slit grooves to communicate with each other, and the sacrificial layer is removed by an etching solution through the communicated slit groove to form a hollow portion. Thereafter, the conductive layer WL is formed by forming a metal layer such as tungsten in the hollow portion. Furthermore, the staircase-side plate-shaped part STLa and the bridge-side plate-shaped part STLb can be formed by forming an insulating film in the slit groove or a stacked film including a semiconductor film, a metal film, and an insulating film in the slit.

Alternatively, prior to the replacement process, a slit groove penetrating the first precursor multi-layered body LM1′, the second precursor multi-layered body LM2′, and the third precursor multi-layered body LM3′ may be formed after the support column part 10 is formed. Here, the slit groove is formed so that a part thereof overlaps an end portion of the support column part 10 in the X direction. Thereafter, a hollow portion is formed by removing the sacrificial layer through the slit groove with an etching solution. Thereafter, a metal layer such as tungsten is formed in the hollow portion to form the conductive layer WL. Furthermore, the staircase-side plate-shaped part STLa and the bridge-side plate-shaped part STLb may be formed by forming an insulating film in the slit groove or a stacked film including a semiconductor film, a metal film, and an insulating film in the slit.

In the replacement process described above, the etching solution reaches the sacrificial layer 23 through the slit grooves of the first precursor multi-layered body LM1′, the second precursor multi-layered body LM2′, and the third precursor multi-layered body LM3′. Therefore, the first multi-layered body LM1, the second multi-layered body LM2, and the third multi-layered body LM3 are formed.

Incidentally, when the support column part hole 20 is formed as shown in FIGS. 16 and 17, and the extending portion 22a is further formed by allowing the etching solution to flow around as shown in FIG. 21, it is preferable that a width in the X direction of a combined portion of the extending portion 10a and protruding portion 10b formed on the support column part 10 be a width necessary for the etching solution to flow around.

As shown in FIG. 22, on a bottom part side of the first multi-layered body LM1, the extension part OL1a of the insulating layer OL1 on the support column part 10 side is formed to be slightly longer than an end portion WLa of the conductive layer WL on the support column part 10 side by etching. For example, the extension part OL1a of the insulating layer OL1 on the support column part 10 side protrudes to the center side of the support column part 10 further than the end portion WLa of the conductive layer WL on the support column part 10 side. Therefore, a recessed portion 26 is formed between the upper and lower extension parts OL1a and OL1a adjacent in the Z direction. The end portion WLa of the conductive layer WL is disposed on the bottom part side of the recessed portion 26.

In order to reliably form the recessed portion 26 on the bottom part side of the first multi-layered body LM1, as described above, it is preferable that a width in the X direction of the combined portion of the extending portion 10a and protruding portion 10b formed on the support column part 10 be a width necessary to form the recessed portion 26 through reliable flow-around of the etching solution.

As shown in FIG. 22, on the bottom part side of the support column part 10, the end portions WLa of the conductive layers WL adjacent in the Z direction are close to each other. Therefore, this can be a cause of leakage current generation.

Here, if the extension part OL1a of the insulating layer OL1 is formed longer than the end portion WLa of the conductive layer WL, it is possible to suppress wraparound current that may occur between the end portions WLa of the conductive layers WL disposed in the Z direction. Therefore, it is possible to improve a leakage breakdown voltage of transistors formed in the cell array region CA.

On the other hand, if the width in the X direction of the combined portion of the extending portion 10a and protruding portion 10b formed on the support column part 10 is too large, an amount of the above-described flow-around of the etching solution is reduced, and a shape of the recessed portion 26 is distorted. For example, when the recessed portion 26 becomes shallower, a distance between the end portions WLa of the conductive layers WL adjacent in the vertical direction via the recessed portion 26 becomes smaller. Therefore, there is a likelihood that the leakage breakdown voltage will decrease.

When the sacrificial layer 23 is replaced with the conductive layer WL and the support column part 10 is formed after forming each hole by processes described above, a cross-sectional structure shown in FIGS. 17, 19, and 20 is obtained. The structure shown in FIGS. 17, 19 and 20 is equivalent to the structure of the first embodiment described above based on FIGS. 3 to 8.

In the first embodiment described above, the support column parts 10 are disposed at predetermined intervals in the X direction as shown in FIG. 1. Also, in the second embodiment, as shown in the cross section of FIG. 13, the first support column part 10A is disposed in the staircase-side plate-shaped part STLa of the first multi-layered body LM1. When viewed from a planar layout shown in FIG. 1, the first support column parts 10A are disposed at predetermined intervals in the X direction similarly to the configuration shown in FIG. 1. However, disposition of the support column parts 10 and 10A is not limited to those examples.

For example, when a support column part is to be provided in any of the first multi-layered body LM1, the second multi-layered body LM2, and the third multi-layered body LM3, it is most preferable to provide a support column part in all of the first multi-layered body LM1, the second multi-layered body LM2, and the third multi-layered body LM3. Alternatively, it is preferable to provide the support column part 10A only in the first multi-layered body LM1. Alternatively, the support column part 10A may be provided in the first multi-layered body LM1, and the support column part 10B may be provided in the second multi-layered body LM2.

When a plurality of multi-layered bodies are stacked such as the multi-layered structure of the first multi-layered body LM1, the second multi-layered body LM2, and the third multi-layered body LM3, deformation such as warping or distortion is most likely to occur in a lowermost multi-layered body. Therefore, it is necessary to provide the support column part 10A in the lowermost first multi-layered body LM1 at a minimum.

In the following description, a disposition pattern of the support column parts provided in any of the first multi-layered body LM1, the second multi-layered body LM2, and the third multi-layered body LM3 will be described.

In the following description, “provided in any of” means any of “a case in which the support column part is provided only in the first multi-layered body LM1 in the staircase-side plate-shaped part STLa”, “a case in which the support column part is provided in the first multi-layered body LM1 and the second multi-layered body LM2 in the staircase-side plate-shaped part STLa”, “in a case in which the support column part is provided in the first multi-layered body LM1, the second multi-layered body LM2, and the third multi-layered body LM3 in the staircase-side plate-shaped part STLa”, or “in a case in which the support column part is provided in all the multi-layered bodies in the staircase-side plate-shaped part STLa and the bridge-side plate-shaped part STLb”.

### Third Embodiment

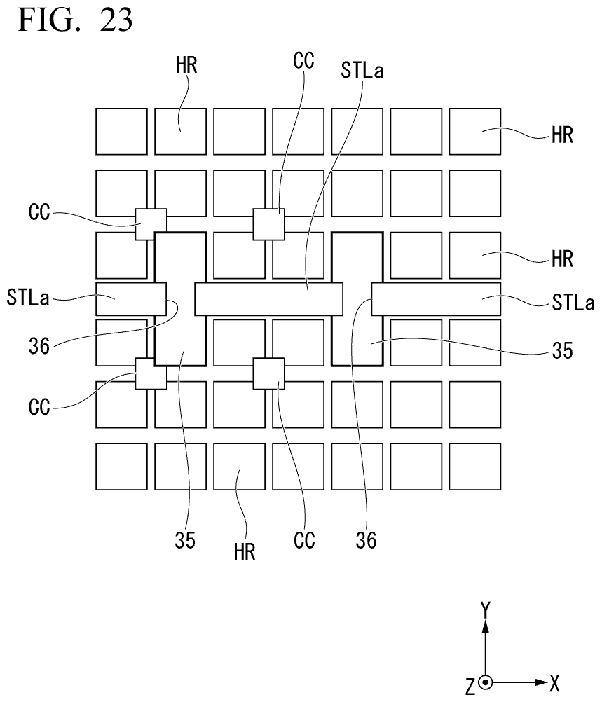

FIG. 23 shows a third embodiment relating to a disposition pattern of support column parts provided in any of a first multi-layered body LM1, a second multi-layered body LM2, and a third multi-layered body LM3 constituting a semiconductor storage device.

In the third embodiment shown in FIG. 23, positions at which columnar portions HR are disposed are indicated by squares for the sake of simplifying the drawing. Positions of contacts CC disposed on both sides of a staircase-side plate-shaped part STLa in a Y direction (both sides in a width direction) are simply indicated by squares.

In a plan view of the staircase-side plate-shaped part STLa shown in FIG. 23, a support column part 35 is formed to occupy a first position and a second position. The first position is a position of the columnar portion HR disposed on one side of the staircase-side plate-shaped part STLa in the Y direction. The second position is a position of the columnar portion HR disposed on the other side of the staircase-side plate-shaped part STLa in the Y direction. Also, in the drawings described below, the staircase-side plate-shaped part STLa is schematically shown as a single-layered structure for simplification of the drawings.

In the embodiment, intermittent portions 36 are formed at predetermined intervals in an X direction of the staircase-side plate-shaped part STLa. The support column part 35 is formed at a position crossing the staircase-side plate-shaped part STLa in the Y direction via the intermittent portion 36. The position at which the support column part 35 is formed corresponds to a position in which one of the regions in which the columnar portions HR are adjacent in the Y direction with the staircase-side plate-shaped part STLa interposed therebetween is replaced by the support column part 35.

In FIG. 23, the first multi-layered body LM1, the second multi-layered body LM2, and the third multi-layered body LM3 are not shown in the drawings. In a case of a structure in which the first multi-layered body LM1, the second multi-layered body LM2, and the third multi-layered body LM3 are stacked in a Z direction, the support column part 35 is disposed to penetrate the first multi-layered body LM1 to the third multi-layered body LM3 in the Z direction. In the example shown in FIG. 23, the support column part 35 protrudes in the Y direction. An end portion of the support column part 35 in the Y direction is disposed farther from the staircase-side plate-shaped part STLa than a center position of the columnar portion HR closest to the staircase-side plate-shaped part STLa in the Y direction. Alternatively, the support column part 35 and the closest columnar portion HR may be understood as being integrated. Alternatively, it may be understood that the support column part 35 connects the columnar portions HR to each other across the staircase-side plate-shaped part STLa.

In the semiconductor storage device having the support column part 35 with the disposition pattern shown in FIG. 23, it is possible to obtain the same operation and effects as those of the first embodiment described above.

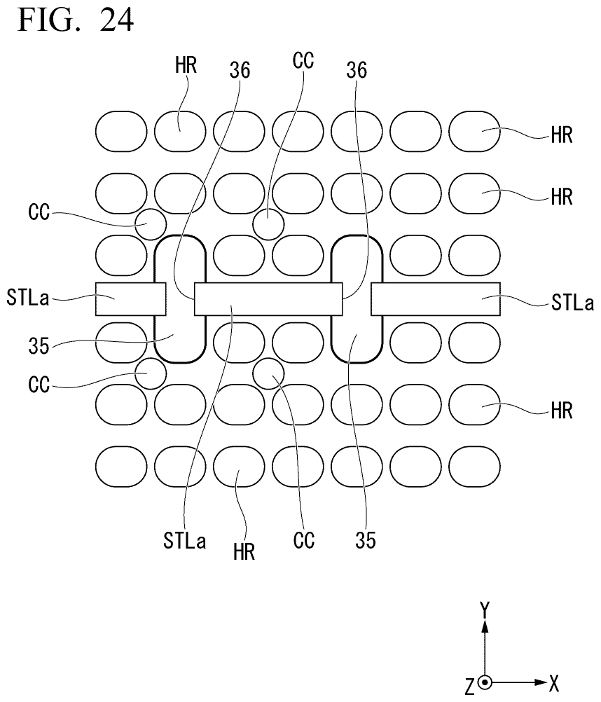

Furthermore, in FIG. 23, a shape of the columnar portion HR in a plan view is shown as a square. A shape of the contact CC in a plan view is also shown as a square. Examples of a shape of the support column part 35 in a plan view and a shape of the contact CC in a plan view that are applied to an actual semiconductor storage device are shapes shown in FIG. 24.

As shown in FIG. 24, the columnar portion HR has, for example, a racetrack shape in a plan view. The contact CC can be formed in a circular shape.

In the description of the following embodiments, for the purpose of simplifying the drawings, shapes of the columnar portions HR in a plan view are all shown as squares, and shapes of the contacts CC in a plan view are all shown as squares in a simplified manner.

### Fourth Embodiment

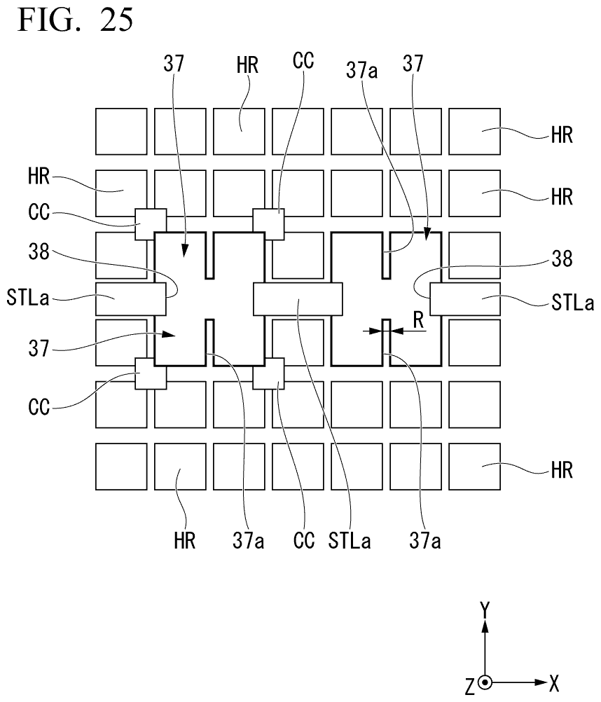

FIG. 25 shows a fourth embodiment relating to a disposition pattern of support column parts provided in any of a first multi-layered body LM1, a second multi-layered body LM2, and a third multi-layered body LM3 constituting a semiconductor storage device.

In a plan view of a staircase-side plate-shaped part STLa in FIG. 25, a support column part 37 is formed at a position in which four adjacent columnar portions HR are to be disposed, in place of the four columnar portions HR.

In the embodiment, intermittent portions 38 are formed at predetermined intervals in an X direction of the staircase-side plate-shaped part STLa. The support column part 37 is formed at a position crossing the staircase-side plate-shaped part STLa in a Y direction via the intermittent portion 38. The position at which the support column part 37 is formed corresponds to a region in which a total of four columnar portions HR are to be disposed adjacent to each other in XY directions with the staircase-side plate-shaped part STLa interposed therebetween. A length of the intermittent portion 38 in the X direction is greater than a length of one columnar portion HR in the X direction.

In FIG. 25, the first multi-layered body LM1, the second multi-layered body LM2, and the third multi-layered body LM3 are not shown in the drawings. In a case of a structure in which the first multi-layered body LM1, the second multi-layered body LM2, and the third multi-layered body LM3 are stacked in a Z direction, the support column part 37 is disposed to penetrate the first multi-layered body LM1 to the third multi-layered body LM3 in the Z direction.

Also, in a plan view as shown in FIG. 25, the support column part 37 has recessed portions 37a at an end in a +Y direction and an end in a −Y direction of a center portion of the support column part 37 in the X direction. A width of the recessed portion 37a in the X direction is equal to a distance between the columnar portions HR and HR aligned in the X direction. A width R of the recessed portion 37a in the Y direction is slightly smaller than a width of the columnar portion HR in the Y direction. Since the support column part 37 has the recessed portion 37a at the end in the +Y direction and the end in the −Y direction, the support column part 37 is formed in a substantially H-shape in a plan view. In FIG. 25, the staircase-side plate-shaped part STLa positioned on a side in the −X direction of the support column part 37 is formed to partially enter a left side portion of the support column part 37. In FIG. 25, the staircase-side plate-shaped part STLa positioned on a side in the +X direction of the support column part 37 is formed to partially enter a right side portion of the support column part 37.

In FIG. 25, the support column part 37 is formed to occupy positions in which the two columnar portions HR are to be disposed in the X direction. The support column part 37 may be formed to occupy positions in which any number of three or more columnar portions HR are to be formed in the X direction. That is, a width of the support column part 37 in the X direction can be optionally set.

Also in the semiconductor storage device having the support column part 37 with the disposition pattern shown in FIG. 25, it is possible to obtain the same operation and effects as those of the first embodiment described above.

### Fifth Embodiment

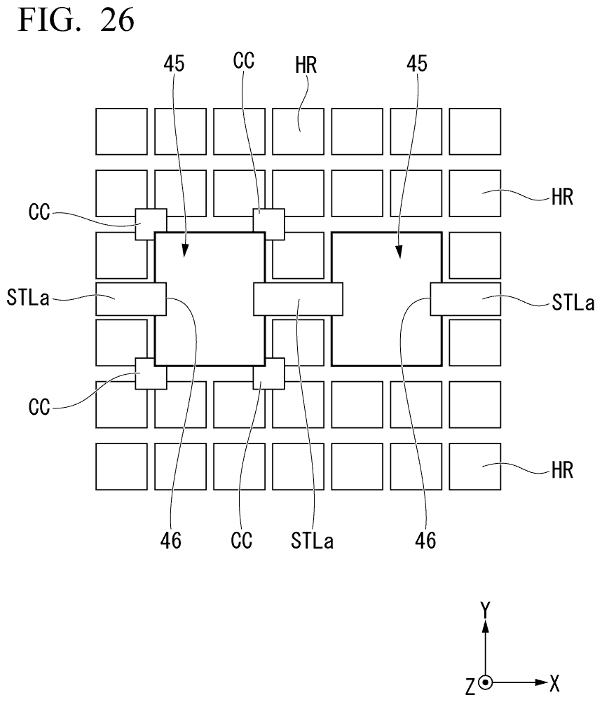

FIG. 26 shows a fifth embodiment relating to a disposition pattern of support column parts provided in any of a first multi-layered body LM1, a second multi-layered body LM2, and a third multi-layered body LM3 constituting a semiconductor storage device.

In a plan view of a staircase-side plate-shaped part STLa shown in FIG. 26, a support column part 45 is formed at positions in which four columnar portions HR adjacent in XY directions are to be disposed, in place of four columnar portions.

In the embodiment, intermittent portions 46 are formed at predetermined intervals in an X direction of the staircase-side plate-shaped part STLa. The support column part 45 is formed to cross the staircase-side plate-shaped part STLa in a Y direction via the intermittent portion 46. The position at which the support column part 45 is formed corresponds to a region in which four columnar portions HR are to be disposed adjacent to each other in the XY direction in a plan view with the staircase-side plate-shaped part STLa interposed therebetween.

In FIG. 26, the first multi-layered body LM1, the second multi-layered body LM2, and the third multi-layered body LM3 are not shown in the drawings. In a case of a structure in which the first multi-layered body LM1, the second multi-layered body LM2, and the third multi-layered body LM3 are stacked in a Z direction, the support column part 45 is disposed to penetrate the first multi-layered body LM1 to the third multi-layered body LM3 in the Z direction.

As shown in the disposition of FIG. 26, the staircase-side plate-shaped part STLa positioned on a side in the −X direction of the support column part 45 is formed to partially enter a left side portion of the support column part 45. In FIG. 26, the staircase-side plate-shaped part STLa positioned on a side in the +X direction of the support column part 45 is formed to partially enter a right side portion of the support column part 45. In a plan view of the support column part 45, the other portions are formed along a rectangular region in which the columnar portions HR are to be formed, and thus the support column part 45 is formed in a substantially quadrangular shape in a plan view.

In FIG. 26, the support column part 45 is formed along a position in which two columnar portions HR are to be disposed in the X direction. The support column part 45 may be formed along a position in which any number of three or more columnar portions HR are to be formed in the X direction. That is, a width of the support column part 45 in the X direction can be optionally set.

Also in the semiconductor storage device having the support column part 45 with the disposition pattern shown in FIG. 26, it is possible to obtain the same operation and effects as those of the first embodiment described above.

### Sixth Embodiment

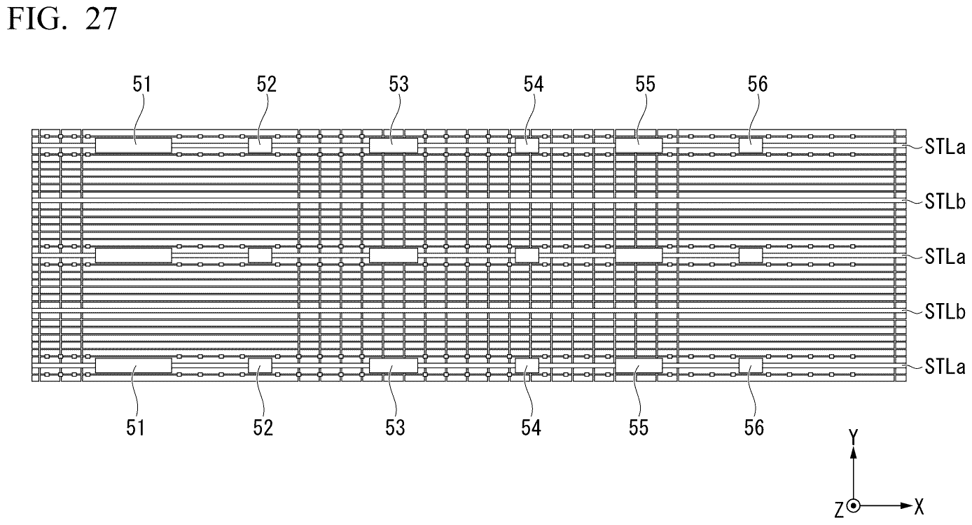

FIG. 27 shows a sixth embodiment relating to a disposition pattern of support column parts provided in any of a first multi-layered body LM1, a second multi-layered body LM2, and a third multi-layered body LM3 constituting a semiconductor storage device.

In the sixth embodiment, support column parts 51, 52, 53, 54, 55, and 56 having different lengths in an X direction are formed at optionally selected intervals in the X direction of a staircase-side plate-shaped part STLa. As an example, lengths of the support column parts in the X direction have the following relationship: support column part 51>support column part 55>support column part 53=support column part 52=support column part 54=support column part 56. As an example, the support column parts 51, 52, 53, 54, 55, and 56 are repeatedly disposed in that order in the X direction of the staircase-side plate-shaped part STLa.

In the semiconductor storage device, a disposition pattern of the support column parts formed in any of the first multi-layered body LM1, the second multi-layered body LM2, and the third multi-layered body LM3 can be optionally selected. The example in FIG. 27 shows one such example.

Also in the semiconductor storage device having the support column parts 51 to 56 with the disposition pattern shown in FIG. 27, it is possible to obtain the same operation and effects as those of the first embodiment described above.

### Seventh Embodiment

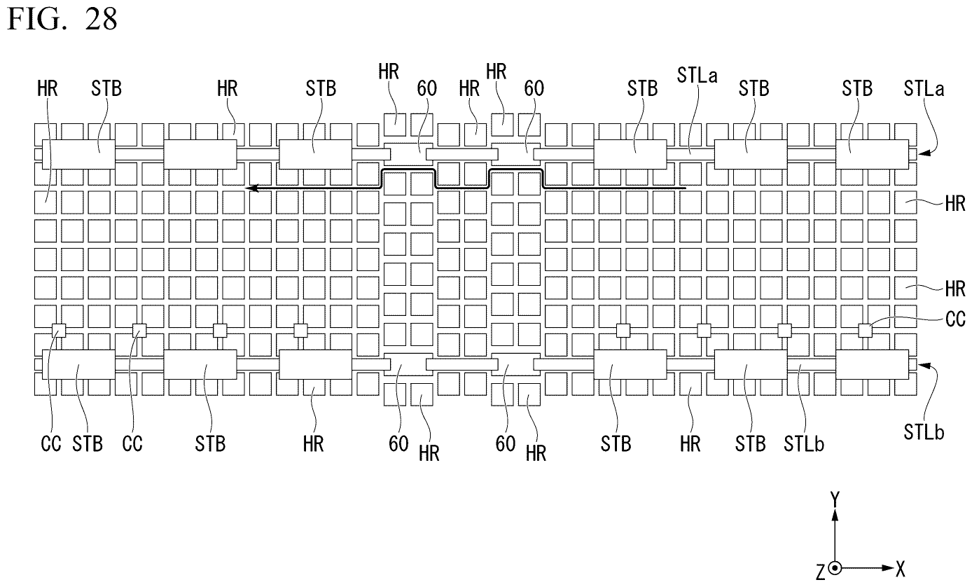

FIG. 28 shows a seventh embodiment relating to a disposition pattern of support column parts provided in any of a first multi-layered body LM1, a second multi-layered body LM2, and a third multi-layered body LM3 constituting a semiconductor storage device.

In the seventh embodiment, a disposition pattern of columnar portions HR is not entirely uniform, and part of the disposition pattern of the columnar portions HR is configured differently.

In the embodiment shown in FIG. 28, the columnar portions HR are disposed at regular intervals in X and Y directions. Also, staircase-side plate-shaped parts STLa and bridge-side plate-shaped parts STLb extending in the X direction are alternately and repeatedly disposed at predetermined intervals in the Y direction.

A plurality of block portions STB described above with reference to FIGS. 7 and 8 are formed at predetermined intervals on the staircase-side plate-shaped part STLa and the bridge-side plate-shaped part STLb. Then, as long as a predetermined number of block portions STB are formed in the X direction of each of the staircase-side plate-shaped part STLa and the bridge-side plate-shaped part STLb, a disposition pattern is repeated in which two support column parts 60 and 60 are disposed at a predetermined interval in the X direction, and a predetermined number of block portions STB are again disposed in the X direction.

In a region in which the two support column parts 60 and 60 are disposed, a disposition pattern of the columnar portions HR is different from that in other regions. A disposition pattern with some positional offset in the Y direction is employed.

In the embodiment shown in FIG. 28, in a region in which the two support column parts 60 and 60 are disposed, a pattern is employed in which the pattern of the columnar portions HR aligned in the Y direction is offset in position by about a fraction of a width of the columnar portion HR in the Y direction compared to other regions.

In the example shown in FIG. 28, a shape of the support column part 60 in a plan view is the same in size as the combined shape of two columnar portions HR adjacent in the X direction in a plan view.

In the semiconductor storage device having the support column part 60 with the disposition pattern shown in FIG. 28, it is possible to obtain the same operation and effects as those of the first embodiment described above.

As shown in FIG. 28, both the support column part 60 and the block portion LTB may be appropriately disposed along the staircase-side plate-shaped part STLa and the bridge-side plate-shaped part STLb to suppress deformation such as warping and distortion that may occur in the multi-layered body.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a staircase region-side multi-layered body including a plurality of conductive layers and a plurality of insulating layers, the staircase region-side multi-layered body having an upper part and a lower part, the plurality of conductive layers and the plurality of insulating layers being alternately stacked one by one, the plurality of conductive layers including a staircase portion, the staircase portion having a staircase shape extending in a first direction intersecting a stacking direction of the plurality of conductive layers;
an interlayer-insulating film covering the staircase portion;
a plate-shaped part extending in the first direction, the plate-shaped part penetrating the staircase region-side multi-layered body in the stacking direction, the plate-shaped part being intermittent in the first direction via an intermittent portion; and
a support column part in the intermittent portion, the support column part penetrating the staircase region-side multi-layered body in the stacking direction to reach the upper part from the lower part.

2. The semiconductor storage device according to claim 1, wherein
regarding end portions of the plurality of insulating layers adjacent to a bottom part side of the support column part and end portions of the plurality of conductive layers adjacent to a bottom part side of the support column part,
the end portions of the plurality of insulating layers have extending portions protruding toward the support column part further than the end portions of the plurality of conductive layers.

3. The semiconductor storage device according to claim 1, comprising a plurality of staircase region-side multi-layered bodies, each of the plurality of staircase region-side multi-layered bodies corresponding to the staircase region-side multi-layered body and stacked in the stacking direction, wherein
all of the plurality of staircase region-side multi-layered bodies have the support column part.

4. The semiconductor storage device according to claim 1, comprising:
a plurality of staircase region-side multi-layered bodies, each of the plurality of staircase region-side multi-layered bodies corresponding to the staircase region-side multi-layered body and being stacked in the stacking direction;
a plurality of staircase region-side multi-layered bodies, each of the plurality of staircase region-side multi-layered bodies corresponding to the staircase region-side multi-layered body and being in a second direction intersecting the first direction;
staircase-side plate-shaped parts penetrating the staircase portion in the stacking direction in the plurality of staircase region-side multi-layered bodies in the second direction, the staircase-side plate-shaped parts being apart from each other in the second direction; and
a bridge-side plate-shaped part penetrating the plurality of staircase region-side multi-layered bodies in the stacking direction between the staircase-side plate-shaped parts, wherein
the intermittent portion and the support column part are in all of the staircase-side plate-shaped part and the bridge-side plate-shaped part.

5. The semiconductor storage device according to claim 1, comprising:
a plurality of staircase region-side multi-layered bodies, each of the plurality of staircase region-side multi-layered bodies corresponding to the staircase region-side multi-layered body and being stacked in the stacking direction;
a plurality of staircase region-side multi-layered bodies, each of the plurality of staircase region-side multi-layered bodies corresponding to the staircase region-side multi-layered body and being in a second direction intersecting the first direction;
staircase-side plate-shaped parts penetrating the staircase portion in the stacking direction in the plurality of staircase region-side multi-layered bodies in the second direction, the staircase-side plate-shaped parts being apart from each other in the second direction; and
a bridge-side plate-shaped part penetrating the plurality of staircase region-side multi-layered bodies in the stacking direction between the staircase-side plate-shaped parts, wherein
the intermittent portion and the support column part are in the staircase-side plate-shaped part penetrating the staircase region-side multi-layered body on a lowermost part side of the plurality of staircase region-side multi-layered bodies stacked in the stacking direction.

6. The semiconductor storage device according to claim 1, comprising a cell array region-side multi-layered body including a plurality of conductive layers and a plurality of insulating layers, the plurality of conductive layers and the plurality of insulating layers being alternately stacked, the cell array region-side multi-layered body including a semiconductor pillar and memory cells, the semiconductor pillar extending in a stacking direction of the plurality of conductive layers and the plurality of insulating layers, and the memory cells being at intersection positions of the plurality of conductive layers and the semiconductor pillar, wherein
the cell array region-side multi-layered body is adjacent to the staircase region-side multi-layered body in the first direction,
the cell array region-side multi-layered body includes a cell array region-side plate-shaped part therein,
the cell array region-side plate-shaped part extends in the first direction,
the cell array region-side plate-shaped part penetrates the cell array region-side multi-layered body in the stacking direction, and
the plate-shaped part on a cell array region side does not have the support column part.

7. A manufacturing method of a semiconductor storage device comprising:
forming a first multi-layered body by stacking a plurality of first insulating layers and a plurality of first sacrificial layers;
forming a first columnar body penetrating the first multi-layered body;
forming a first slit, the first slit extending in a first direction intersecting a stacking direction of the first multi-layered body, the first slit penetrating the first multi-layered body, the first slit overlapping a part of the first columnar body;
forming a second slit, the second slit extending in the first direction, the second slit being apart from the first slit with the first columnar body interposed therebetween, the second slit penetrating the first multi-layered body, the second slit overlapping a part of the first columnar body,
removing the plurality of first sacrificial layers from the first slit and the second slit by etching,
forming a first conductive layer at a portion in which the plurality of first sacrificial layers were present, and
forming a first plate-shaped part and a second plate-shaped part by forming a film in the first slit and the second slit.

8. The manufacturing method of a semiconductor storage device according to claim 7, comprising:
forming a second multi-layered body by stacking a plurality of second insulating layers and a plurality of second sacrificial layers after the first multi-layered body is formed; and
forming the first slit and the second slit to penetrate the first multi-layered body and the second multi-layered body after the second multi-layered body is formed.

9. The manufacturing method of a semiconductor storage device according to claim 7, comprising:
forming a second multi-layered body by stacking a plurality of second insulating layers and a plurality of second sacrificial layers after the first multi-layered body is formed;
forming a second columnar body penetrating the second multi-layered body and at least partially overlapping the first columnar body in a top view; and
forming the first slit and the second slit to penetrate the first multi-layered body and the second multi-layered body and at least partially overlapping the first columnar body and the second columnar body after the second multi-layered body is formed.

10. The manufacturing method of a semiconductor storage device according to

7. comprising: when the first columnar body is formed,
forming a first opening penetrating the first multi-layered body;
etching a part of the first sacrificial layers from the first opening; and
forming the first columnar body by forming a film on the first opening.
